(19) United States
(12) Patent Application Publication
(10) Pub. No.: US 2024/0155920 A1
(43) Pub. Date: May 9, 2024

(54) DISPLAY DEVICE

(71) Applicant: Samsung Display Co., Ltd., Yongin-si (KR)

(72) Inventors: SEUNG-LYONG BOK, Yongin-si (KR); JEONGHO LEE, Yongin-si (KR)

(21) Appl. No.: 18/231,136

(22) Filed: Aug. 7, 2023

(30) Foreign Application Priority Data
Nov. 3, 2022 (KR) 10-2022-0144904

(51) Int. Cl. H10K 59/80; H10K 59/124

(52) U.S. Cl. CPC H10K 59/873; H10K 59/124

(57) ABSTRACT

A display device includes: a base layer; a circuit layer on the base layer, and including a pixel circuit; an element layer on the circuit layer, and including a light emitting element electrically connected with the pixel circuit; and an encapsulation layer covering the element layer. At least one of the base layer or the circuit layer has a groove defined therein, the encapsulation layer covers the groove, and a plurality of spaces are defined in the groove, each of the plurality of spaces being completely surrounded by the encapsulation layer.

### CROSS-REFERENCE TO RELATED APPLICATION

This application claims priority to and the benefit of Korean Patent Application No. 10-2022-0144904, filed on Nov. 3, 2022, in the Korean Intellectual Property Office, the entire disclosure of which is incorporated by reference herein.

### BACKGROUND

### 1. Field

Aspects of embodiments of the present disclosure relate to a display device having improved product reliability.

### 2. Description of Related Art

A display device may be a device constituted by various electronic parts, such as a display panel that displays an image, an input sensor that senses an external input, an electronic module, and the like. The electronic module may include a camera, an infrared sensor, a proximity sensor, or the like. The electronic module may be disposed under the display panel and the input sensor. The display panel and the input sensor may have a hole formed therein for exposing the electronic module.

The above information disclosed in this Background section is for enhancement of understanding of the background of the present disclosure, and therefore, it may contain information that does not constitute prior art.

### SUMMARY

Embodiments of the present disclosure are directed to a display device having improved product reliability.

According to one or more embodiments of the present disclosure, a display device includes: a base layer; a circuit layer on the base layer, and including a pixel circuit; an element layer on the circuit layer, and including a light emitting element electrically connected with the pixel circuit; and an encapsulation layer covering the element layer. At least one of the base layer or the circuit layer has a groove defined therein, the encapsulation layer covers the groove, and a plurality of spaces are defined in the groove, each of the plurality of spaces being completely surrounded by the encapsulation layer.

In an embodiment, the groove may include a sidewall portion including: a first sidewall; a first tip protruding from the first sidewall; a second sidewall on the first tip; and a second tip protruding from the second sidewall.

In an embodiment, a first width of the groove at the first sidewall may be smaller than a second width of the groove at the second sidewall.

In an embodiment, the circuit layer may further include: a plurality of inorganic insulating layers; a first intermediate conductive layer; a first organic layer on the plurality of inorganic insulating layers, and covering the first intermediate conductive layer; and a second intermediate conductive layer on the first organic layer. The first intermediate conductive layer may include a first conductive layer, a second conductive layer, and a third conductive layer sequentially stacked one above another, and the second intermediate conductive layer may include a fourth conductive layer, a fifth conductive layer, and a sixth conductive layer sequentially stacked one above another. The first sidewall may be defined in at least a portion of the second conductive layer; the first tip may be defined by the third conductive layer and the fourth conductive layer; the second sidewall may be defined in the fifth conductive layer; and the second tip may be defined by the sixth conductive layer.

In an embodiment, the first conductive layer, the third conductive layer, the fourth conductive layer, and the sixth conductive layer may include titanium, and the second conductive layer and the fifth conductive layer may include aluminum.

In an embodiment, the plurality of spaces may include: a first space facing the first sidewall; and a second space facing the second sidewall.

In an embodiment, in a cross-sectional view, a maximum width of the first space may be greater than a maximum width of the second space.

In an embodiment, a slope of a direction of the maximum width of the first space may be greater than a slope of a direction of the maximum width of the second space.

In an embodiment, the groove may further include a third sidewall on the second tip, and a third tip protruding from the third sidewall.

In an embodiment, the plurality of spaces may include: a first space facing the first sidewall; a second space facing the second sidewall; and a third space facing the third sidewall. In a cross-sectional view, a first maximum width of the first space may be greater than a second maximum width of the second space, and the second maximum width of the second space may be greater than a third maximum width of the third space.

In an embodiment, a direction of the first maximum width of the first space, a direction of the second maximum width of the second space, and a direction of the third maximum width of the third space may be different from one another.

In an embodiment, a thickness of the first tip may be greater than a thickness of the second tip.

In an embodiment, each of a portion defining the first sidewall and a portion defining the second sidewall may have a thickness of 1 micrometer or less.

In an embodiment, the groove may be defined in the base layer, and may have a depth of 1 micrometer or less.

In an embodiment, the circuit layer may further include: a plurality of inorganic insulating layers; a first intermediate conductive layer; a first organic layer on the plurality of inorganic insulating layers, and covering the first intermediate conductive layer; and a second intermediate conductive layer on the first organic layer. The plurality of inorganic insulating layers may have a tip portion protruding more than a sidewall of the base layer defining the groove.

In an embodiment, the circuit layer may further include: a plurality of inorganic insulating layers; a first intermediate conductive layer; a first organic layer on the plurality of inorganic insulating layers, and covering the first intermediate conductive layer; and a second intermediate conductive layer on the first organic layer. The groove may be defined in the first organic layer, and the second intermediate conductive layer may define a tip portion protruding more than a sidewall of the first organic layer defining the groove.

In an embodiment, the display device may further include a crack dam spaced from the light emitting element, and including: a first layer including the same material as that of the first organic layer; and a second layer including the same material as that of the second intermediate conductive layer. The second layer may protrude more than the first layer, the encapsulation layer may cover the crack dam, and a space completely surrounded by the encapsulation layer may be further defined in a portion facing the first layer.

In an embodiment, the base layer may have a hole, and the crack dam may be located between the hole and the light emitting element.

In an embodiment, the base layer may include: a first region, the light emitting element being located in the first region; and a second region surrounding the first region, the crack dam being located in the second region.

In an embodiment, the encapsulation layer may include: a first inorganic encapsulation layer on the element layer; an organic encapsulation layer on the first inorganic encapsulation layer; and a second inorganic encapsulation layer on the organic encapsulation layer. Each of the plurality of spaces may be surrounded by the first inorganic encapsulation layer.

According to one or more embodiments of the present disclosure, a display device includes: a base layer having a hole defined therein; a pixel on the base layer, and including a first electrode, an intermediate layer, and a second electrode; a protrusion on the base layer between the pixel and the hole, and including: a first sidewall; a first tip protruding from the first sidewall; a second sidewall on the first tip; and a second tip protruding from the second sidewall; an encapsulation layer covering the pixel and the protrusion; and a space completely surrounded by the encapsulation layer. The space faces at least one of the first sidewall or the second sidewall of the protrusion.

In an embodiment, the space may include: a first space facing the first sidewall; and a second space facing the second sidewall.

In an embodiment, in a cross-sectional view, a maximum width of the first space may be greater than a maximum width of the second space.

In an embodiment, a slope of a direction of the maximum width of the first space may be greater than a slope of a direction of the maximum width of the second space.

In an embodiment, the protrusion may include: a first conductive portion including a first conductive layer, a second conductive layer, and a third conductive layer sequentially stacked one above another; and a second conductive portion including a fourth conductive layer, a fifth conductive layer, and a sixth conductive layer sequentially stacked one above another. The first sidewall may be defined in at least a portion of the second conductive layer; the first tip may be defined by the third conductive layer and the fourth conductive layer; the second sidewall may be defined in the fifth conductive layer; and the second tip may be defined by the sixth conductive layer.

In an embodiment, the protrusion may include a plurality of protrusions. The first conductive layer and the second conductive layer of the plurality of protrusions may be connected with each other, and the third conductive layer, the fourth conductive layer, the fifth conductive layer, and the sixth conductive layer of the plurality of protrusions may be spaced from each other.

In an embodiment, the first conductive layer, the third conductive layer, the fourth conductive layer, and the sixth conductive layer may include titanium, and the second conductive layer and the fifth conductive layer may include aluminum.

In an embodiment, a minimum width of the first conductive portion may be greater than a minimum width of the second conductive portion.

In an embodiment, the protrusion may include a plurality of protrusions, and a maximum interval between the first conductive portions of the plurality of protrusions may be smaller than a maximum interval between the second conductive portions of the plurality of protrusions.

In an embodiment, a thickness of the first tip may be greater than a thickness of the second tip.

In an embodiment, the protrusion may further include a third sidewall on the second tip, and a third tip protruding from the third sidewall.

In an embodiment, the space may include: a first space facing the first sidewall; a second space facing the second sidewall; and a third space facing the third sidewall. In a cross-sectional view, a first maximum width of the first space may be greater than a second maximum width of the second space, and the second maximum width of the second space may be greater than a third maximum width of the third space.

In an embodiment, a direction of the first maximum width of the first space, a direction of the second maximum width of the second space, and a direction of the third maximum width of the third space may be different from one another.

In an embodiment, each of a portion defining the first sidewall of the protrusion and a portion defining the second sidewall of the protrusion may have a thickness of 1 micrometer or less.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a perspective view of an electronic device according to an embodiment of the present disclosure.

FIG. 2A is an exploded perspective view of the electronic device according to an embodiment of the present disclosure.

FIG. 2B is a block diagram of the electronic device according to an embodiment of the present disclosure.

FIG. 3 is a plan view of a display panel according to an embodiment of the present disclosure.

FIG. 4 is an equivalent circuit diagram of a pixel according to an embodiment of the present disclosure.

FIG. 5 is a sectional view of the display panel according to an embodiment of the present disclosure.

FIG. 6 is a sectional view of the display panel according to an embodiment of the present disclosure.

FIG. 7A is an enlarged sectional view of the region AA′ of FIG. 6 according to an embodiment of the present disclosure.

FIG. 7B is an enlarged sectional view of the region AA′ of FIG. 6 according to an embodiment of the present disclosure.

FIG. 7C is an enlarged sectional view of the region AA′ of FIG. 6 according to an embodiment of the present disclosure.

FIG. 8 is an enlarged sectional view of the region AA′ of FIG. 6 according to an embodiment of the present disclosure.

FIG. 9A is an enlarged sectional view of the region AA′ of FIG. 6 according to an embodiment of the present disclosure.

FIG. 9B is an enlarged sectional view of the region AA′ of FIG. 6 according to an embodiment of the present disclosure.

FIG. 10 is a sectional view of the display panel according to an embodiment of the present disclosure.

FIG. 11 is a sectional view of the display panel according to an embodiment of the present disclosure.

FIG. 12 is a sectional view of the display panel according to an embodiment of the present disclosure.

FIG. 13 is a sectional view of the display panel according to an embodiment of the present disclosure.

FIG. 14 is a sectional view of the display panel according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

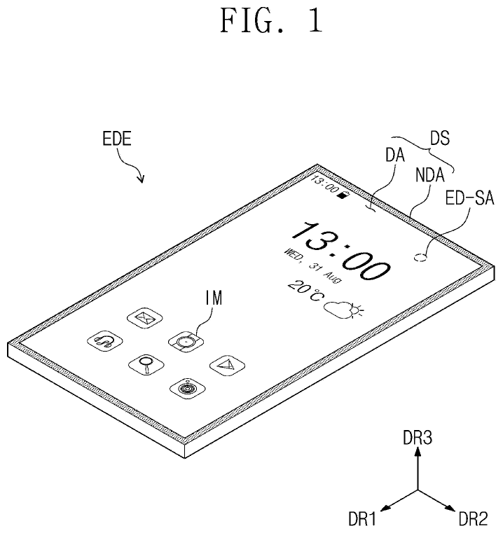

FIG. 1 is a perspective view of an electronic device EDE according to an embodiment of the present disclosure.

Referring to FIG. 1, the electronic device EDE according to an embodiment of the present disclosure may include a display surface DS defined by a first direction DR1 and a second direction DR2 crossing the first direction DR1. The electronic device EDE may provide an image IM to a user through the display surface DS.

The display surface DS may include a display region DA, and a non-display region NDA around (e.g., adjacent to) the display region DA. The display region DA may display the image IM, and the non-display region NDA may not display the image IM. The non-display region NDA may surround (e.g., around a periphery of) the display region DA. However, the present disclosure is not limited thereto, and the shape of the display region DA and the shape of the non-display region NDA may be variously modified as needed or desired. In an embodiment of the present disclosure, the non-display region NDA may be omitted.

Hereinafter, a direction that is perpendicular to or substantially perpendicular to a plane defined by the first direction DR1 and the second direction DR2 is defined as a third direction DR3. In addition, as used herein, the expressions “on the plane” and “in a plan view” may refer to an object portion that it is viewed in/from the third direction DR3.

A sensor region ED-SA may be defined in the display region DA of the electronic device EDE. Although one sensor region ED-SA is illustrated as an example in FIG. 1, the number of sensor regions ED-SA is not limited thereto. The sensor region ED-SA may be surrounded (e.g., around a periphery thereof) by the display region DA. Accordingly, the electronic device EDE may not display an image through the senor region ED-SA.

An electronic module (e.g., an electronic sensor or component) may be disposed in a region overlapping with the sensor region ED-SA. The electronic module may receive an external input transferred through the sensor region ED-SA, or may provide an output through the sensor region ED-SA. For example, the electronic module may be a camera module (e.g., a camera), a sensor that measures a distance, such as a proximity sensor, a sensor that recognizes a part of the user's body (e.g., a fingerprint, an iris, or a face), or a small lamp that outputs light, but is not particularly limited thereto. Hereinafter, for convenience, the electronic module overlapping with the sensor region ED-SA may be described in more detail in the context of a camera module (e.g., a camera).

Although the electronic device EDE of a bar type (e.g., a bar shape) is illustrated as an example in FIG. 1, the present disclosure is not limited thereto. For example, in some embodiments, the electronic device EDE may be a flexible electronic device, for example, such as a foldable electronic device, a rollable electronic device, or a slidable electronic device.

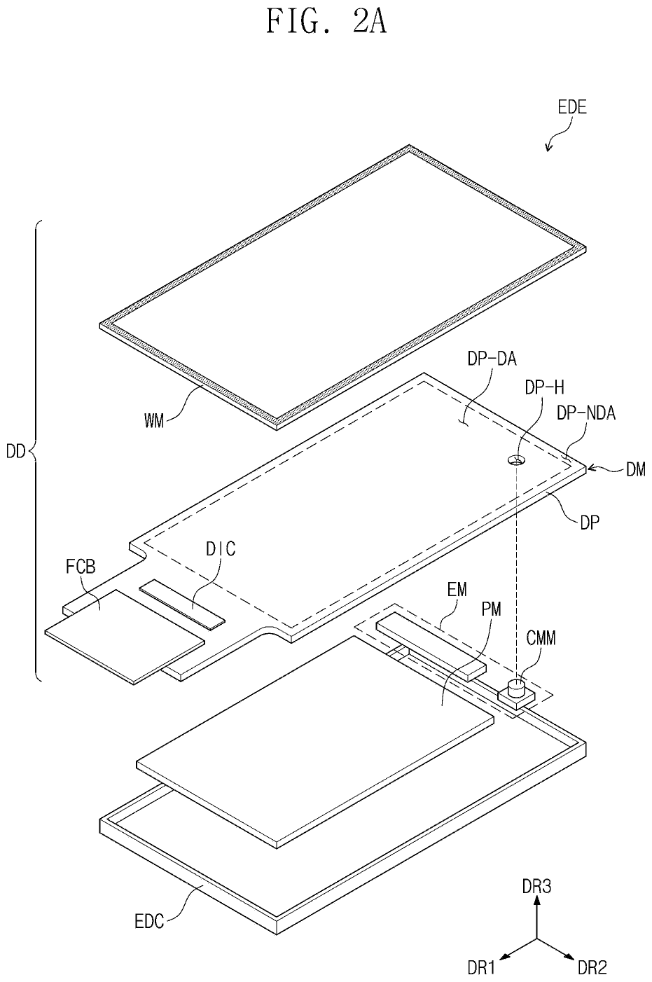

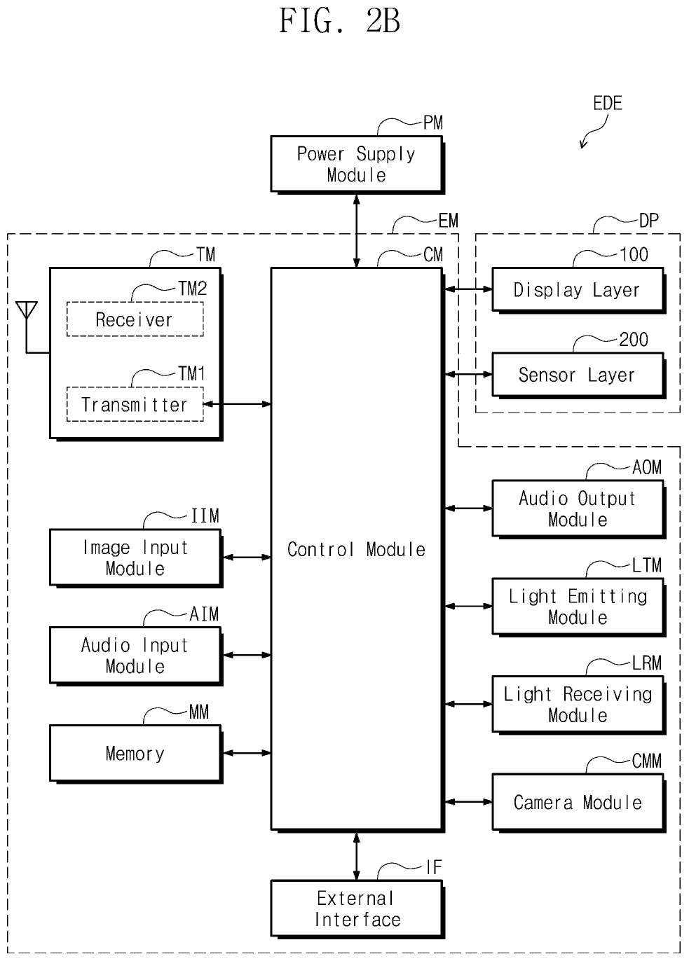

FIG. 2A is an exploded perspective view of the electronic device EDE according to an embodiment of the present disclosure. FIG. 2B is a block diagram of the electronic device EDE according to an embodiment of the present disclosure.

Referring to FIGS. 2A and 2B, the electronic device EDE may include a display device DD, an electronic module (e.g., an electronic sensor or component) EM, a power supply module (e.g., a power supply) PM, and a housing EDC.

The display device DD includes a window module (e.g., a window) WM and a display module (e.g., a display or a touch-display) DM. The window module WM provides a front surface of the electronic device EDE. The display module DM may include at least a display panel DP. The display module DM generates an image, and may detect an external input.

In FIG. 2A, the display module DM is illustrated as being the same component as the display panel DP. However, the display module DM may be or substantially may be a stacked structure in which a plurality of components including the display panel DP are stacked one above another.

The display panel DP includes a display region DP-DA and a non-display region DP-NDA, which correspond to the display region DA and the non-display region NDA (e.g., refer to FIG. 1) of the electronic device EDE, respectively. The expression one region/portion “corresponds to” another region/portion as used herein may refer to the regions/portions overlapping with each other, and is not limited to having the same area as each other.

A hole DP-H may be defined in the display panel DP. For example, the hole DP-H may be defined by removing a portion of the display panel DP. The display region DP-DA of the display panel DP may surround (e.g., around a periphery of) the hole DP-H.

The hole DP-H may overlap with, or may correspond to, the sensor region ED-SA (e.g., refer to FIG. 1) of the electronic device EDE. Although the hole DP-H is illustrated as having a circular shape, the hole DP-H may have various suitable shapes, such as a polygonal shape, an oval shape, a shape having at least one curved side, an irregular shape, or the like, and thus, is not limited to any particular embodiment.

The display panel DP may include a display layer 100 and a sensor layer 200.

The display layer 100 may be a component that generates or substantially generates an image. The display layer 100 may be an emissive display layer. For example, the display layer 100 may be an organic light emitting display layer, an inorganic light emitting display layer, an organic-inorganic light emitting display layer, a quantum-dot display layer, a micro-LED display layer, or a nano-LED display layer.

The sensor layer 200 may sense an external input applied from the outside. The external input may be a user input. The user input may include various suitable kinds of external inputs, such as a part of the user's body, a pen, light, heat, or pressure.

The display module DM may include a driver integrated circuit (IC) DIC disposed on the non-display region DP-NDA. The display module DM may further include a flexible circuit film FCB connected to (e.g., attached to or coupled to) the non-display region DP-NDA.

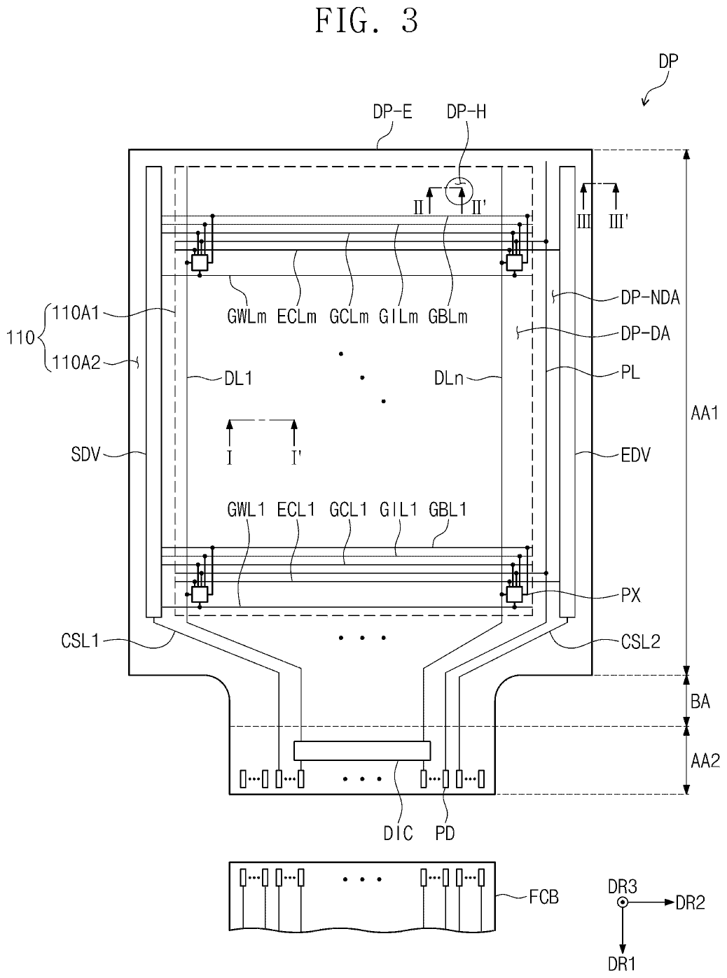

The driver IC DIC may include one or more drive elements (e.g., a data drive circuit) for driving pixels PX (e.g., see FIG. 3) of the display panel DP. Although FIG. 2A illustrates a structure in which the driver IC DIC is mounted on the display panel DP, the present disclosure is not limited thereto. For example, the driver IC DIC may be mounted on the flexible circuit film FCB.

The power supply module PM supplies power used for the overall operations of the electronic device EDE. The power supply module PM may include a battery module (e.g., a battery).

The electronic module EM includes various suitable functional modules for operating the electronic device EDE. The electronic module EM may be directly mounted on a mother board that is electrically connected with the display panel DP, or may be mounted on a separate circuit board and electrically connected to the mother board through a connector.

The electronic module EM may include a control module (e.g., a controller) CM, a wireless communication module (e.g., a wireless communication device) TM, an image input module (e.g., an image input device) IIM, an audio input module (e.g., an audio input device) AIM, memory MM, an external interface IF, an audio output module (e.g., an audio output device) AOM, a light emitting module (e.g., a light emitting device) LTM, a light receiving module (e.g., a light receiving device or sensor) LRM, and a camera module (e.g., a camera) CMM.

The control module CM controls the overall operations of the electronic device EDE. The control module CM may be a microprocessor. For example, the control module CM activates or deactivates the display panel DP. The control module CM may control the other modules, such as the image input module IIM and/or the audio input module AIM, based on a touch signal received from the display panel DP.

The wireless communication module TM may communicate with an external electronic device through a first network (e.g., a short-range communications network, such as Bluetooth, WiFi direct, or infrared data association (IrDA)) and/or a second network (e.g., a long-range communications network, such as a cellular network, the Internet, or a computer network (e.g., LAN or WAN)). Communication modules (e.g., communication devices) included in the wireless communication module TM may be integrated into one component (e.g., a single chip), or may be implemented as a plurality of components (e.g., a plurality of chips) that are separated (e.g., distinct) from one another. The wireless communication module TM may transmit/receive audio signals using a general communications line. The wireless communication module TM may include a transmitter TM1 that modulates a signal to be transmitted and transmits the modulated signal, and a receiver TM2 that demodulates a received signal.

The image input module IIM processes an image signal to covert the image signal into image data that may be displayed on the display panel DP. The audio input module AIM receives an external audio signal through a microphone in a voice recording mode or a voice recognition mode, and converts the external audio signal into electrical voice data.

The external interface IF may include a connector capable of physically connecting the electronic device EDE and an external electronic device to each other. For example, the external interface IF serves as an interface that may be connected to an external charger, a wired/wireless data port, or a card (e.g., a memory card or a SIM-UIM card) socket.

The audio output module AOM converts audio data received from the wireless communication module TM or audio data stored in the memory MM, and outputs the converted data to the outside.

The light emitting module LTM generates and outputs light. The light emitting module LTM may output infrared light. The light emitting module LTM may include an LED element. The light receiving module LRM may sense infrared light. The light receiving module LRM may be activated when infrared light that is above a suitable level (e.g., a predetermined level) is sensed. The light receiving module LRM may include a CMOS sensor. Infrared light generated by the light emitting module LTM may be output and reflected by an external object (e.g., the user's finger or face), and the reflected infrared light may be incident on the light receiving module LRM.

The camera module CMM may take a still image and/or a video. A plurality of camera modules (e.g., a plurality of cameras) CMM may be provided. A part of the camera modules CMM may overlap with the hole DP-H. An external input (e.g., light) may be provided to the camera module CMM through the hole DP-H. For example, the camera module CMM may take an external image by receiving natural light through the hole DP-H.

The housing EDC accommodates the display module DM, the electronic module EM, and the power supply module PM. The housing EDC protects the components accommodated therein, such as the display module DM, the electronic module EM, and the power supply module PM. The housing EDC may be connected to (e.g., attached or coupled with) the window module WM.

FIG. 3 is a plan view of the display panel DP according to an embodiment of the present disclosure.

Referring to FIG. 3, the display panel DP may include a base layer 110, the pixels PX, a scan driver SDV, a data driver, and an emission driver EDV.

The display region DP-DA and the non-display region DP-NDA around (e.g., adjacent to) the display region DP-DA may be defined in the display panel DP. The display region DP-DA and the non-display region DP-NDA may be distinguished from each other depending on whether or not the pixels PX are disposed. The pixels PX are disposed in the display region DP-DA. The scan driver SDV, the data driver, and the emission driver EDV may be disposed in the non-display region DP-NDA. The data driver may be a circuit that is configured in the driver IC DIC.

A first region 110A1 and a second region 110A2 may be defined in the base layer 110. The first region 110A1 of the base layer 110 may overlap with the display region DP-DA. The second region 110A2 of the base layer 110 may overlap with the non-display region DP-NDA. In other words, the first region 110A1 of the base layer 110 may be a base surface on which the components disposed in the display region DA are provided, and the second region 110A2 of the base layer 110 may be a base surface on which the components disposed in the non-display region DP-NDA are provided.

The display panel DP may include a first panel region AA1, a bending region BA, and a second panel region AA2, which are defined along the first direction DR1. The second panel region AA2 and the bending region BA may be partial regions of the non-display region DP-NDA. The bending region BA is disposed between the first panel region AA1 and the second panel region AA2.

The first panel region AA1 is a region corresponding to the display surface DS of FIG. 1. The width (e.g., or the length) of the bending region BA and the width (e.g., or the length) of the second panel region AA2 that are parallel to or substantially parallel to the second direction DR2 may be smaller than the width (e.g., or the length) of the first panel region AA1 that is parallel to or substantially parallel to the second direction DR2. A region having a smaller length in the direction of a bending axis may be more easily bent.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a drive voltage line PL, and a plurality of pads PD. Here, “m” and “n” are natural numbers of 2 or more.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the second direction DR2, and may be electrically connected to the scan driver SDV. The data lines DL1 to DLn may extend in the first direction DR1, and may be electrically connected to the driver IC DIC via the bending region BA. The emission control lines ECL1 to ECLm may extend in the second direction DR2, and may be electrically connected to the emission driver EDV.

The drive voltage line PL may include a portion extending in the first direction DR1 and a portion extending in the second direction DR2. The portion extending in the first direction DR1 and the portion extending in the second direction DR2 may be disposed at (e.g., in or on) different layers from each other. The portion of the drive voltage line PL that extends in the first direction DR1 may extend to the second panel region AA2 via the bending region BA. The drive voltage line PL may provide a drive voltage to the pixels PX.

The first control line CSL1 may be connected to the scan driver SDV, and may extend toward a lower end of the second panel region AA2 via the bending region BA. The second control line CSL2 may be connected to the emission driver EDV, and may extend toward the lower end of the second panel region AA2 via the bending region BA.

The pads PD may be disposed to be adjacent to the lower end of the second panel region AA2 when viewed on the plane (e.g., in a plan view). The driver IC DIC, the drive voltage line PL, the first control line CSL1, and the second control line CSL2 may be electrically connected to the pads PD. The flexible circuit film FCB may be electrically connected to the pads PD through an anisotropic conductive adhesive layer.

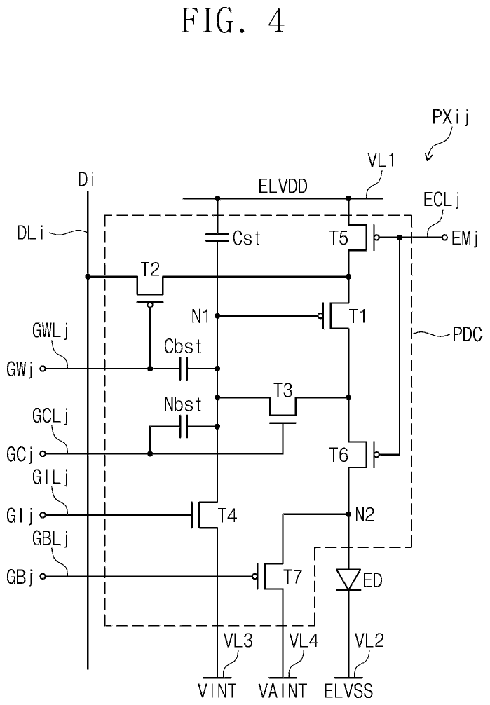

FIG. 4 is an equivalent circuit diagram of a pixel PXij according to an embodiment of the present disclosure.

FIG. 4 illustrates the equivalent circuit diagram of the pixel PXij from among the plurality of pixels PX (e.g., refer to FIG. 3). The plurality of pixels PX may have the same or substantially the same circuit structure as each other. Therefore, the circuit structure for the pixel PXij described in more detail hereinafter may be applied to the other remaining pixels PX in the same or substantially the same manner, and thus, redundant description of the other remaining pixels PX may not be repeated.

Referring to FIGS. 3 and 4, the pixel PXij is connected to an i-th data line DLi from among the data lines DL1 to DLn, a j-th initialization scan line GILj from among the initialization scan lines GIL1 to GILm, a j-th compensation scan line GCLj from among the compensation scan lines GCL1 to GCLm, a j-th write scan line GWLj from among the write scan lines GWL1 to GWLm, a j-th black scan line GBLj from among the black scan lines GBL1 to GBLm, a j-th emission control line ECLj from among the emission control lines ECL1 to ECLm, first and second drive voltage lines VL1 and VL2, and first and second initialization voltage lines VL3 and VL4. Here, “i” is an integer from among 1 to n, and “j” is an integer from among 1 to m.

The pixel PXij includes a light emitting element ED and a pixel circuit PDC. The light emitting element ED may be a light emitting diode. In an embodiment of the present disclosure, the light emitting element ED may be an organic light emitting diode including an organic light emitting layer, but is not particularly limited thereto. The pixel circuit PDC may control the amount of current flowing through the light emitting element ED in response to a data signal Di. The light emitting element ED may emit light having a desired luminance (e.g., a predetermined luminance) in response to the amount of current provided from the pixel circuit PDC.

The pixel circuit PDC may include first to seventh transistors T1, T2, T3, T4, T5, T6, and T7, and first to third capacitors Cst, Cbst, and Nbst. A configuration of the pixel circuit PDC according to the present disclosure is not limited to the embodiment illustrated in FIG. 4. The pixel circuit PDC illustrated in FIG. 4 is provided as an example, and various suitable changes and modifications may be made to the configuration of the pixel circuit PDC as needed or desired.

At least one of the first to seventh transistors T1, T2, T3, T4, T5, T6, and T7 may be a transistor having a low-temperature polycrystalline silicon (LTPS) semiconductor layer. At least one of the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

In more detail, the first transistor T1 may directly affect the brightness of the light emitting element ED, and thus, may include a semiconductor layer formed of polycrystalline silicon having high reliability. Accordingly, the display device having a high resolution may be implemented. On the other hand, an oxide semiconductor has high carrier mobility and low leakage current, and therefore, a voltage drop may not be great even though an operating time is long. In other words, the color of an image may not be greatly changed depending on a voltage drop even during a low-frequency operation, and therefore, the low-frequency operation may be possible. Because the oxide semiconductor has low leakage current as described above, at least one of the third transistor T3, which is connected with a gate electrode of the first transistor T1, or the fourth transistor T4 may be employed as an oxide semiconductor to reduce power consumption, while preventing or substantially preventing a leakage current that may flow to the gate electrode.

Some of the first to seventh transistors T1, T2, T3, T4, T5, T6, and T7 may be P-type transistors, and the others may be N-type transistors. For example, the first, second, fifth, sixth, and seventh transistors T1, T2, T5, T6, and T7 may be P-type transistors, and the third and fourth transistors T3 and T4 may be N-type transistors.

A configuration of the pixel circuit PDC according to the present disclosure is not limited to the embodiment illustrated in FIG. 4. The pixel circuit PDC illustrated in FIG. 4 is provided as an example, and various suitable changes and modifications may be made to the configuration of the pixel circuit PDC. For example, the first to seventh transistors T1, T2, T3, T4, T5, T6, and T7 may all be P-type transistors or N-type transistors. As another example, the first, second, fifth, and sixth transistors T1, T2, T5, and T6 may be P-type transistors, and the third, fourth, and seventh transistors T3, T4, and T7 may be N-type transistors.

The j-th initialization scan line GILj, the j-th compensation scan line GCLj, the j-th write scan line GWLj, the j-th black scan line GBLj, and the j-th emission control line ECLj may transfer the j-th initialization scan signal GIj, the j-th compensation scan signal GCj, the j-th write scan signal GWj, the j-th black scan signal GBj, and the j-th emission control signal EMj, respectively, to the pixel PXji. The i-th data line DLi transfers the i-th data signal Di to the pixel PXij. The i-th data signal Di may have a voltage level corresponding to an image signal that is input to the display device DD (e.g., refer to FIG. 2A).

The first and second drive voltage lines VL1 and VL2 may transfer a first drive voltage ELVDD and a second drive voltage ELVSS, respectively, to the pixel PXij. The first and second initialization voltage lines VL3 and VL4 may transfer a first initialization voltage VINT and a second initialization voltage VAINT, respectively, to the pixel PXij.

The first transistor T1 is connected between the first drive voltage line VL1 for receiving the first drive voltage ELVDD and the light emitting element ED. The first transistor T1 includes a first electrode connected with the first drive voltage line VL1 via the fifth transistor T5, a second electrode connected with a pixel electrode (e.g., an anode) of the light emitting element ED via the sixth transistor T6, and a third electrode (e.g., the gate electrode) connected with one end of the first capacitor Cst (e.g., at a first node N1). The first transistor T1 may receive the i-th data signal Di that the i-th data line DLi transfers depending on a switching operation of the second transistor T2, and may supply a drive current to the light emitting element ED.

The second transistor T2 is connected between the i-th data line DLi and the first electrode of the first transistor T1. The second transistor T2 includes a first electrode connected with the i-th data line DLi, a second electrode connected with the first electrode of the first transistor T1, and a third electrode (e.g., a gate electrode) connected with the j-th write scan line GWLj. The second transistor T2 may be turned on in response to the j-th write scan signal GWj transferred through the j-th write scan line GWLj, and may transfer, to the first electrode of the first transistor T1, the i-th data signal Di transferred from the i-th data line DLi. One end of the second capacitor Cbst may be connected to the third electrode of the second transistor T2, and an opposite end of the second capacitor Cbst may be connected to the first node N1.

The third transistor T3 is connected between the second electrode of the first transistor T1 and the first node N1. The third transistor T3 includes a first electrode connected with the third electrode of the first transistor T1, a second electrode connected with the second electrode of the first transistor T1, and a third electrode (e.g., a gate electrode) connected with the j-th compensation scan line GCLj. The third transistor T3 may be turned on in response to the j-th compensation scan signal GCj transferred through the j-th compensation scan line GCLj, and may diode-connect the first transistor T1 by connecting the third electrode of the first transistor T1 and the second electrode of the first transistor T1 to each other. One end of the third capacitor Nbst may be connected to the third electrode of the third transistor T3, and an opposite end of the third capacitor Nbst may be connected to the first node N1.

The fourth transistor T4 is connected between the first initialization voltage line VL3 through which the first initialization voltage VINT is applied and the first node N1. The fourth transistor T4 includes a first electrode connected with the first initialization voltage line VL3 through which the first initialization voltage VINT is transferred, a second electrode connected with the first node N1, and a third electrode (e.g., a gate electrode) connected with the j-th initialization scan line GILj. The fourth transistor T4 is turned on in response to the j-th initialization scan signal GIj transferred through the j-th initialization scan line GILj. The turned-on fourth transistor T4 initializes a potential of the third electrode of the first transistor T1 (e.g., the potential of the first node N1) by transferring the first initialization voltage VINT to the first node N1.

The fifth transistor T5 includes a first electrode connected with the first drive voltage line VL1, a second electrode connected with the first electrode of the first transistor T1, and a third electrode (e.g., a gate electrode) connected to the j-th emission control line ECLj. The sixth transistor T6 includes a first electrode connected with the second electrode of the first transistor T1, a second electrode connected to the pixel electrode of the light emitting element ED, and a third electrode (e.g., a gate electrode) connected to the j-th emission control line ECLj.

The fifth and sixth transistors T5 and T6 are concurrently (e.g., simultaneously or substantially simultaneously) turned on with each other in response to the j-th emission control signal EMj transferred through the j-th emission control line ECLj. The first drive voltage ELVDD applied through the turned-on fifth transistor T5 may be compensated for through the diode-connected first transistor T1, and may be transferred to the light emitting element ED through the sixth transistor T6.

The seventh transistor T7 includes a first electrode connected to the second initialization voltage line VL4 through which the second initialization voltage VAINT is transferred, a second electrode connected with the second electrode of the sixth transistor T6 and a second node N2, and a third electrode (e.g., a gate electrode) connected with the j-th black scan line GBLj. The second initialization voltage VAINT may have a voltage level lower than or equal to the voltage level of the first initialization voltage VINT.

The one end of the first capacitor Cst is connected with the third electrode of the first transistor T1, and an opposite end of the first capacitor Cst is connected with the first drive voltage line VL1. A cathode of the light emitting element ED may be connected with the second drive voltage line VL2 that transfers the second drive voltage ELVSS. The second drive voltage ELVSS may have a lower voltage level than that of the first drive voltage ELVDD.

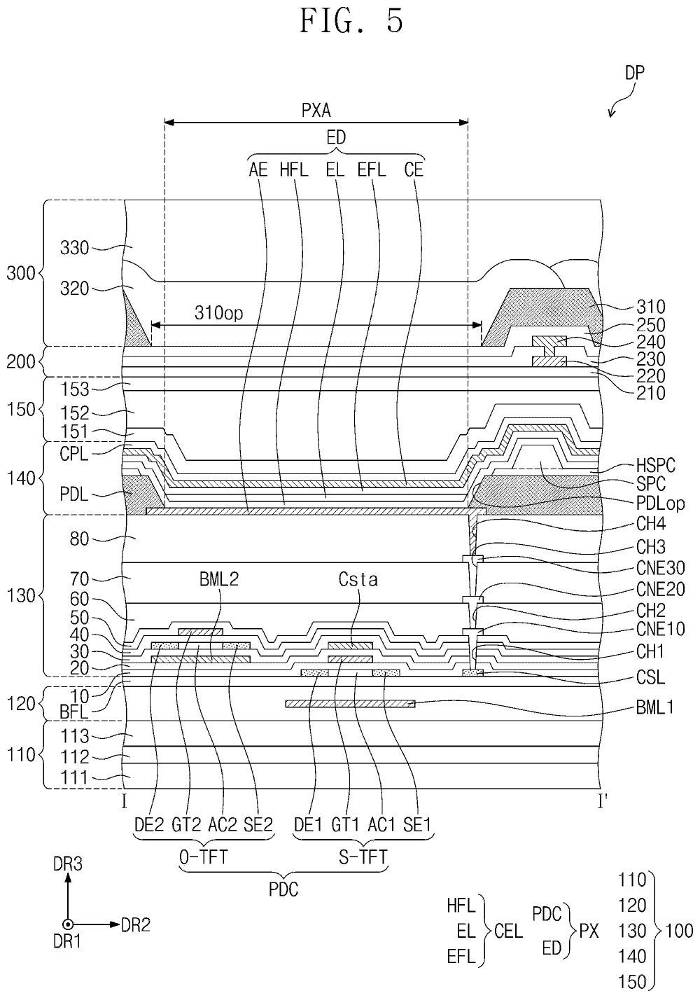

FIG. 5 is a sectional view of the display panel DP according to an embodiment of the present disclosure. For example, FIG. 5 may be a cross-sectional view taken along the line I-I′ of FIG. 3.

Referring to FIG. 5, the display panel DP may include the display layer 100, the sensor layer 200, and an anti-reflection layer 300. The display layer 100 may include a base layer 110, a barrier layer 120, a circuit layer 130, an element layer 140, and an encapsulation layer 150.

The base layer 110 may include first to third sub-base layers 111, 112, and 113. Each of the first sub-base layer 111 and the third sub-base layer 113 may include at least one of a polyimide-based resin, an acrylate-based resin, a methacrylate-based resin, a polyisoprene-based resin, a vinyl-based resin, an epoxy-based resin, a urethane-based resin, a celluose-based resin, a siloxane-based resin, a polyamide-based resin, or a perylene-based resin. As used herein, a “˜˜”-based resin may refer to a resin including a “˜˜” functional group. For example, each of the first sub-base layer 111 and the third sub-base layer 113 may include polyimide.

The second sub-base layer 112 may have a single-layer structure or a multi-layered structure. For example, the second sub-base layer 112 may include an inorganic material, and may include at least one of silicon oxide, silicon nitride, silicon oxy-nitride, or amorphous silicon. For example, the second sub-base layer 112 may include silicon oxy-nitride, and silicon oxide stacked thereon.

The barrier layer 120 may be disposed on the base layer 110. The barrier layer 120 may have a single-layer structure or a multi-layered structure. The barrier layer 120 may include at least one of silicon oxide, silicon nitride, silicon oxy-nitride, or amorphous silicon.

The barrier layer 120 may further include a first lower light blocking layer BML1. For example, in the case in which the barrier layer 120 has a multi-layered structure, the first lower light blocking layer BML1 may be disposed between the layers constituting the barrier layer 120. However, without being limited thereto, the first lower light blocking layer BML1 may be disposed between the base layer 110 and the barrier layer 120, or may be disposed above the barrier layer 120. In an embodiment, the first lower light blocking layer BML1 may be omitted. The first lower light blocking layer BML1 may be referred to as a first lower layer, a first lower metal layer, a first lower electrode layer, a first lower shielding layer, a first light blocking layer, a first metal layer, a first shielding layer, or a first overlap layer.

A buffer layer BFL may be disposed on the barrier layer 120. The buffer layer BFL may prevent or substantially prevent diffusion of metal atoms and/or impurities from the base layer 110 to a first semiconductor pattern. Furthermore, the buffer layer BFL may allow the first semiconductor pattern to be uniformly or substantially uniformly formed, by adjusting the speed at which heat is provided during a crystallization process for forming the first semiconductor pattern.

The buffer layer BFL may include a plurality of inorganic layers. For example, the buffer layer BFL may include a first sub-buffer layer including silicon nitride, and a second sub-buffer layer disposed on the first sub-buffer layer and including silicon oxide.

The circuit layer 130 may be disposed on the buffer layer BFL, and the element layer 140 may be disposed on the circuit layer 130. As described above, a pixel PX may include the pixel circuit PDC, and the light emitting element ED electrically connected to the pixel circuit PDC. The pixel circuit PDC may be included in the circuit layer 130, and the light emitting element ED may be included in the element layer 140.

A silicon thin film transistor S-TFT and an oxide thin film transistor O-TFT of the pixel circuit PDC are illustrated as an example in FIG. 5. The silicon thin film transistor S-TFT may be one of the first, second, fifth, sixth, and seventh transistors T1, T2, T5, T6, and T7 described above with reference to FIG. 4, and the oxide thin film transistor O-TFT may be one of the third and fourth transistors T3 and T4.

The first semiconductor pattern may be disposed on the buffer layer BFL. The first semiconductor pattern may include a silicon semiconductor. For example, the silicon semiconductor may include amorphous silicon or polycrystalline silicon. For example, the first semiconductor pattern may include low-temperature poly silicon.

FIG. 5 illustrates a portion of the first semiconductor pattern that is disposed on the buffer layer BFL, and the first semiconductor pattern may be additionally disposed in other regions. The first semiconductor pattern may be arranged across the pixels PX according to a suitable rule (e.g., a specific or predetermined rule). The first semiconductor pattern may have different electrical properties depending on whether or not the first semiconductor pattern is doped. The first semiconductor pattern may include a first region having a high conductivity and a second region having a low conductivity. The first region may be doped with an N-type dopant or a P-type dopant. A P-type transistor may include a doped region that is doped with a P-type dopant, and an N-type transistor may include a doped region that is doped with an N-type dopant. The second region may be an undoped region, or may be a region that is more lightly doped than the first region.

The first region may have a higher conductivity than that of the second region, and may serve or substantially serve as an electrode or a signal line. The second region may correspond to or substantially correspond to an active region (e.g., a channel) of a transistor. In other words, one portion of the first semiconductor pattern may be an active region of the transistor, another portion may be a source or drain of the transistor, and another portion may be a connecting electrode or a connecting signal line.

A source region SE1, an active region AC1, and a drain region DE1 of the silicon thin film transistor S-TFT may be formed from the first semiconductor pattern. The source region SE1 and the drain region DE1 may extend from the active region AC1 in opposite directions from each other on the section (e.g., in a cross-sectional view).

A portion of a connecting signal line CSL formed from the first semiconductor pattern is illustrated in FIG. 5. The connecting signal line CSL may be electrically connected to the second electrode of the sixth transistor T6 (e.g., refer to FIG. 4) and to the second electrode of the seventh transistor T7.

The circuit layer 130 may include a plurality of inorganic layers and a plurality of organic layers. In an embodiment, first to fifth insulating layers 10, 20, 30, 40, and 50 sequentially stacked on the buffer layer BFL may be the inorganic layers, and sixth to eighth insulating layers 60, 70, and 80 may be the organic layers.

The first insulating layer 10 may be disposed on the buffer layer BFL. The first insulating layer 10 may cover the first semiconductor pattern. The first insulating layer 10 may be an inorganic layer and/or an organic layer, and may have a single-layer structure or a multi-layered structure. The first insulating layer 10 may include at least one of aluminum oxide, titanium oxide, silicon oxide, silicon nitride, silicon oxy-nitride, zirconium oxide, or hafnium oxide. In the present embodiment, the first insulating layer 10 may be a single silicon oxide layer. Similar to the first insulating layer 10, the insulating layers of the circuit layer 130 described in more detail below may have a single-layer structure or a multi-layered structure.

A gate electrode GT1 of the silicon thin film transistor S-TFT may be disposed on the first insulating layer 10. The gate electrode GT1 may be a portion of a metal pattern. The gate electrode GT1 overlaps with the active region AC1. The gate electrode GT1 may function as a mask in a process of doping the first semiconductor pattern. The gate electrode GT1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), or indium zinc oxide (IZO), but is not particularly limited thereto.

The second insulating layer 20 may be disposed on the first insulating layer 10, and may cover the gate electrode GT1. The second insulating layer 20 may be an inorganic layer, and may have a single-layer structure or a multi-layered structure. The second insulating layer 20 may include at least one of silicon oxide, silicon nitride, or silicon oxy-nitride. In the present embodiment, the second insulating layer 20 may have a single-layer structure including a silicon nitride layer.

The third insulating layer 30 may be disposed on the second insulating layer 20. The third insulating layer 30 may be an inorganic layer, and may have a single-layer structure or a multi-layered structure. For example, the third insulating layer 30 may have a multi-layered structure including a silicon oxide layer and a silicon nitride layer. One electrode Csta of the first capacitor Cst (e.g., refer to FIG. 4) may be disposed between the second insulating layer 20 and the third insulating layer 30. Furthermore, the other electrode of the first capacitor Cst may be disposed between the first insulating layer 10 and the second insulating layer 20. For example, in some embodiments, the gate electrode GT1 may serve as the other electrode of the first capacitor Cst.

A second semiconductor pattern may be disposed on the third insulating layer 30. The second semiconductor pattern may include an oxide semiconductor. The oxide semiconductor may include a plurality of regions that are distinguished from each other depending on whether or not a metal oxide is reduced. A region where the metal oxide is reduced (hereinafter, referred to as the reduced region) has a higher conductivity than a region where the metal oxide is not reduced (hereinafter, referred to as the non-reduced region). The reduced region serves or substantially serves as a source/drain of a transistor or a signal line. The non-reduced region corresponds to or substantially corresponds to an active region (e.g., a semiconductor region or a channel) of the transistor. In other words, one portion of the second semiconductor pattern may be an active region of the transistor, another portion may be a source/drain region of the transistor, and another portion may be a signal transmission region.

A source region SE2, an active region AC2, and a drain region DE2 of the oxide thin film transistor O-TFT may be formed from the second semiconductor pattern. The source region SE2 and the drain region DE2 may extend from the active region AC2 in opposite directions from each other on the section (e.g., in a cross-sectional view).

The fourth insulating layer 40 may be disposed on the third insulating layer 30. The fourth insulating layer 40 may cover the second semiconductor pattern. The fourth insulating layer 40 may be an inorganic layer, and may have a single-layer structure or a multi-layered structure. The fourth insulating layer 40 may include at least one of aluminum oxide, titanium oxide, silicon oxide, silicon nitride, silicon oxy-nitride, zirconium oxide, or hafnium oxide. In the present embodiment, the fourth insulating layer 40 may have a single-layer structure including silicon oxide.

A gate electrode GT2 of the oxide thin film transistor O-TFT may be disposed on the fourth insulating layer 40. The gate electrode GT2 may be a portion of a metal pattern. The gate electrode GT2 overlaps with the active region AC2. The gate electrode GT2 may function as a mask in a process of reducing the second semiconductor pattern.

A second lower light blocking layer BML2 may be disposed under the oxide thin film transistor O-TFT. The second lower light blocking layer BML2 may be disposed between the second insulating layer 20 and the third insulating layer 30. The second lower light blocking layer BML2 may include the same material as that of the one electrode Csta of the first capacitor Cst (e.g., refer to FIG. 4), and may be formed through the same process as that of the one electrode Csta of the first capacitor Cst.

The fifth insulating layer 50 may be disposed on the fourth insulating layer 40, and may cover the gate electrode GT2. The fifth insulating layer 50 may be an inorganic layer and/or an organic layer, and may have a single-layer structure or a multi-layered structure. For example, the fifth insulating layer 50 may have a multi-layered structure including a silicon oxide layer and a silicon nitride layer.

A first connecting electrode CNE10 may be disposed on the fifth insulating layer 50. The first connecting electrode CNE10 may be connected to the connecting signal line CSL through a first contact hole CH1 penetrating the first to fifth insulating layers 10, 20, 30, 40, and 50.

The sixth insulating layer 60 may be disposed on the fifth insulating layer 50. A second connecting electrode CNE20 may be disposed on the sixth insulating layer 60. The second connecting electrode CNE20 may be connected to the first connecting electrode CNE10 through a second contact hole CH2 penetrating the sixth insulating layer 60.

The seventh insulating layer 70 may be disposed on the sixth insulating layer 60, and may cover the second connecting electrode CNE20.

A third connecting electrode CNE30 may be disposed on the seventh insulating layer 70. The third connecting electrode CNE30 may be connected to the second connecting electrode CNE20 through a third contact hole CH3 penetrating the seventh insulating layer 70. The eighth insulating layer 80 may be disposed on the seventh insulating layer 70, and may cover the third connecting electrode CNE30.

The sixth insulating layer 60, the seventh insulating layer 70, and the eighth insulating layer 80 may be organic layers. For example, each of the sixth insulating layer 60, the seventh insulating layer 70, and the eighth insulating layer 80 may include a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylate-based polymer, an imide-based polymer, an aryl ether-based polymer, an amide-based polymer, a fluorine-based polymer, a p-xylene-based polymer, a vinyl alcohol-based polymer, or a suitable blend thereof.

The light emitting element ED may include a first electrode AE, a first functional layer HFL, an emissive layer EL, a second functional layer EFL, and a second electrode CE. The first functional layer HFL, the second functional layer EFL, and the second electrode CE may be commonly provided for the pixels PX (e.g., refer to FIG. 3). The first functional layer HFL, the emissive layer EL, and the second functional layer EFL may be referred to as an intermediate layer CEL. The first electrode AE may be referred to as the pixel electrode or the anode, and the second electrode CE may be referred to as the common electrode or the cathode.

The first electrode AE may be disposed on the eighth insulating layer 80. The first electrode AE may be connected to the third connecting electrode CNE30, which is electrically connected to the pixel circuit PDC, through a fourth contact hole CH4 penetrating the eighth insulating layer 80.

In an embodiment of the present disclosure, the third connecting electrode CNE30 may be omitted. In this case, the first electrode AE may penetrate the seventh and eighth insulating layers 70 and 80, and may be connected to the second connecting electrode CNE20. Furthermore, in an embodiment of the present disclosure, the third connecting electrode CNE30 and the eighth insulating layer 80 may be omitted. In this case, the first electrode AE may be disposed on the seventh insulating layer 70, may penetrate the seventh insulating layer 70, and may be connected to the second connecting electrode CNE20.

The first electrode AE may be a transflective electrode, a transmissive electrode, or a reflective electrode. According to an embodiment, the first electrode AE may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a suitable compound thereof, and a transparent or translucent electrode layer formed on the reflective layer. The transparent or translucent electrode layer may include at least one selected from the group consisting of indium tin oxide (ITO), indium zinc oxide (IZO), indium gallium zinc oxide (IGZO), zinc oxide, indium oxide, and aluminum-doped zinc oxide. For example, the first electrode AE may include a multi-layered structure in which indium tin oxide, silver, and indium tin oxide are sequentially stacked.

A pixel defining layer PDL may be disposed on the eighth insulating layer 80. The pixel defining layer PDL may have a property of absorbing light. For example, the pixel defining layer PDL may be black in color. The pixel defining layer PDL may include a black coloring agent. The black coloring agent may include a black dye or a black pigment. The black coloring agent may include carbon black, a metal such as chromium, or a suitable oxide thereof.

An opening PDLop for exposing a portion of the first electrode AE may be defined in (e.g., may penetrate) the pixel defining layer PDL. In other words, the pixel defining layer PDL may cover a periphery of the first electrode AE. An emissive region PXA may be defined by the pixel defining layer PDL.

A spacer HSPC may be disposed on the pixel defining layer PDL. A protruding spacer SPC may be disposed on the spacer HSPC. The spacer HSPC and the protruding spacer SPC may be integrally formed with each other, and may be formed of the same material as each other. For example, the spacer HSPC and the protruding spacer SPC may be formed through the same process as each other by a half-tone mask. However, the present disclosure is not limited thereto. For example, the spacer HSPC and the protruding spacer SPC may include different materials from each other, and may be formed by separate processes from each other.

The first functional layer HFL may be disposed on the first electrode AE, the pixel defining layer PDL, the spacer HSPC, and the protruding spacer SPC. The first functional layer HFL may include a hole transport layer (HTL), a hole injection layer (HIL), or both the hole transport layer and the hole injection layer. The first functional layer HFL may be disposed in the entire display region DP-DA (e.g., refer to FIG. 3).

The emissive layer EL may be disposed on the first functional layer HFL, and may be disposed in a region corresponding to the opening PDLop of the pixel defining layer PDL. The emissive layer EL may include an organic material, an inorganic material, or an organic-inorganic material that emits a suitable colored light (e.g., a predetermined colored light).

The second functional layer EFL may be disposed on the first functional layer HFL, and may cover the emissive layer EL. The second functional layer EFL may include an electron transport layer (ETL), an electron injection layer (EIL), or both the electron transport layer and the electron injection layer. The second functional layer EFL may be disposed in the entire display region DP-DA (e.g., refer to FIG. 3).

The second electrode CE may be disposed on the second functional layer EFL. The second electrode CE may be disposed in the display region DP-DA (e.g., refer to FIG. 3).

The element layer 140 may further include a capping layer CPL disposed on the second electrode CE. The capping layer CPL may serve to improve a light emission efficiency by a principle of constructive interference. The capping layer CPL may include, for example, a material having a refractive index of 1.6 or more for light having a wavelength of 589 nm. The capping layer CPL may be an organic capping layer including an organic material, an inorganic capping layer including an inorganic material, or a composite capping layer including an organic material and an inorganic material. For example, the capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, or a suitable combination thereof. A substituent including O, N, S, Se, Si, F, Cl, Br, I, or a suitable combination thereof may be selectively substituted for the carbocyclic compound, the heterocyclic compound, and the amine group-containing compound.

The encapsulation layer 150 may be disposed on the element layer 140. The encapsulation layer 150 may include a first inorganic encapsulation layer 151, an organic encapsulation layer 152, and a second inorganic encapsulation layer 153, which are sequentially stacked one above another. The first and second inorganic encapsulation layers 151 and 153 may protect the element layer 140 from moisture and/or oxygen, and the organic encapsulation layer 152 may protect the element layer 140 from foreign matter, such as dust particles.

In an embodiment of the present disclosure, a low-refractive index layer may be additionally disposed between the capping layer CPL and the encapsulation layer 150. The low-refractive index layer may include lithium fluoride. The low-refractive index layer may be formed by a thermal deposition method.

The sensor layer 200 may be disposed on the display layer 100. The sensor layer 200 may be referred to as a sensor, an input sensing layer, or an input sensing panel. The sensor layer 200 may include a sensor base layer 210, a first sensor conductive layer 220, a sensor insulating layer 230, a second sensor conductive layer 240, and a sensor cover layer 250.

The sensor base layer 210 may be directly disposed on the display layer 100. The sensor base layer 210 may be an inorganic layer including at least one of silicon nitride, silicon oxy-nitride, or silicon oxide. As another example, the sensor base layer 210 may be an organic layer including an epoxy resin, an acrylic resin, or an imide-based resin. The sensor base layer 210 may have a single-layer structure, or may have a multi-layered structure that is stacked in the third direction DR3.

Each of the first sensor conductive layer 220 and the second sensor conductive layer 240 may have a single-layer structure, or may have a multi-layered structure that is stacked in the third direction DR3.

A conductive layer having a single-layer structure may include a metal layer or a transparent conductive layer. The metal layer may include molybdenum, silver, titanium, copper, aluminum, or a suitable alloy thereof. The transparent conductive layer may include a transparent conductive oxide, such as indium tin oxide (ITO), indium zinc oxide (IZO), zinc oxide, or indium zinc tin oxide (IZTO). In addition, the transparent conductive layer may include a conductive polymer, such as poly(3,4-ethylenedioxythiophene) (PEDOT), a metal nano wire, or graphene.

A conductive layer having a multi-layered structure may include a plurality of metal layers. The metal layers may have, for example, a three-layered structure of titanium (Ti)/aluminum (Al)/titanium (Ti). The conductive layer having a multi-layered structure may include at least one metal layer and at least one transparent conductive layer.

The sensor insulating layer 230 may be disposed between the first sensor conductive layer 220 and the second sensor conductive layer 240. The sensor insulating layer 230 may include an inorganic film. The inorganic film may include at least one of aluminum oxide, titanium oxide, silicon oxide, silicon nitride, silicon oxy-nitride, zirconium oxide, or hafnium oxide.

As another example, the sensor insulating layer 230 may include an organic film. The organic film may include at least one of an acrylate-based resin, a methacrylate-based resin, a polyisoprene-based resin, a vinyl-based resin, an epoxy-based resin, a urethane-based resin, a celluose-based resin, a siloxane-based resin, a polyimide-based resin, a polyamide-based resin, or a perylene-based resin.

The sensor cover layer 250 may be disposed on the sensor insulating layer 230, and may cover the second sensor conductive layer 240. The second sensor conductive layer 240 may include a conductive pattern. The sensor cover layer 250 may cover the conductive pattern, and may reduce or eliminate a probability of damage to the conductive pattern in a subsequent process. The sensor cover layer 250 may include an inorganic material. For example, the sensor cover layer 250 may include silicon nitride, but is not particularly limited thereto. In an embodiment of the present disclosure, the sensor cover layer 250 may be omitted.

The anti-reflection layer 300 may be disposed on the sensor layer 200. The anti-reflection layer 300 may include a dividing layer 310, a plurality of color filters 320, and a planarization layer 330.

The dividing layer 310 may be disposed to overlap with the conductive pattern of the second sensor conductive layer 240. The sensor cover layer 250 may be disposed between the dividing layer 310 and the second sensor conductive layer 240. The dividing layer 310 may prevent or substantially prevent a reflection of external light by the second sensor conductive layer 240. A material constituting the dividing layer 310 is not particularly limited, as long as it is a suitable material capable of absorbing light. The dividing layer 310 may be a layer having a black color. In an embodiment, the dividing layer 310 may include a black coloring agent. The black coloring agent may include a black dye or a black pigment. The black coloring agent may include carbon black, a metal such as chromium, or a suitable oxide thereof.

The dividing layer 310 may have a dividing opening 310op defined therein (e.g., penetrating therethrough). The dividing opening 310op may overlap with the emissive layer EL. The color filter 320 may be disposed to correspond to the dividing opening 310op. The color filter 320 may transmit light provided from the emissive layer EL overlapping with the color filter 320.

The planarization layer 330 may cover the dividing layer 310 and the color filter 320. The planarization layer 330 may include an organic material, and may provide a flat or substantially flat surface at (e.g., in or on) an upper surface of the planarization layer 330. In an embodiment, the planarization layer 330 may be omitted.

In an embodiment of the present disclosure, the anti-reflection layer 300 may include a reflection control layer instead of the color filters 320. For example, in FIG. 5, the color filter 320 may be omitted, and the reflection control layer may be added to the position where the color filter 320 was located. The reflection control layer may selectively absorb light in a partial band of light reflected inside the display panel and/or the electronic device, or light in a partial band of light incident from outside the display panel and/or the electronic device.

For example, the reflection control layer may absorb light in a first wavelength region of 490 nm to 505 nm and a second wavelength region of 585 nm to 600 nm, and thus, the light transmittance in the first wavelength region and the second wavelength region may be 40% or less. The reflection control layer may absorb light outside the wavelength ranges of red light, green light, and blue light emitted from the emissive layers EL. Because the reflection control layer absorbs light outside the wavelength range of the red light, the green light, or the blue light emitted from the emissive layers EL as described above, a decrease in the luminance of the display panel and/or the electronic device may be prevented, minimized, or reduced. In addition, deterioration in the light emission efficiency of the display panel and/or the electronic device may be prevented, minimized, or reduced, and visibility may be improved.

The reflection control layer may be implemented with an organic layer including a dye, a pigment, or a suitable combination thereof. The reflection control layer may include a tetraazaporphyrin (TAP)-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, or a suitable combination thereof.

In an embodiment, the reflection control layer may have a transmittance of about 64% to about 72%. The transmittance of the reflection control layer may be variously adjusted depending on the content of the pigment and/or dye included in the reflection control layer.

In an embodiment of the present disclosure, the anti-reflection layer 300 may include a phase retarder and/or a polarizer. The anti-reflection layer 300 may include at least a polarizer film. In this case, the anti-reflection layer 300 may be attached to the sensor layer 200 through an adhesive layer.

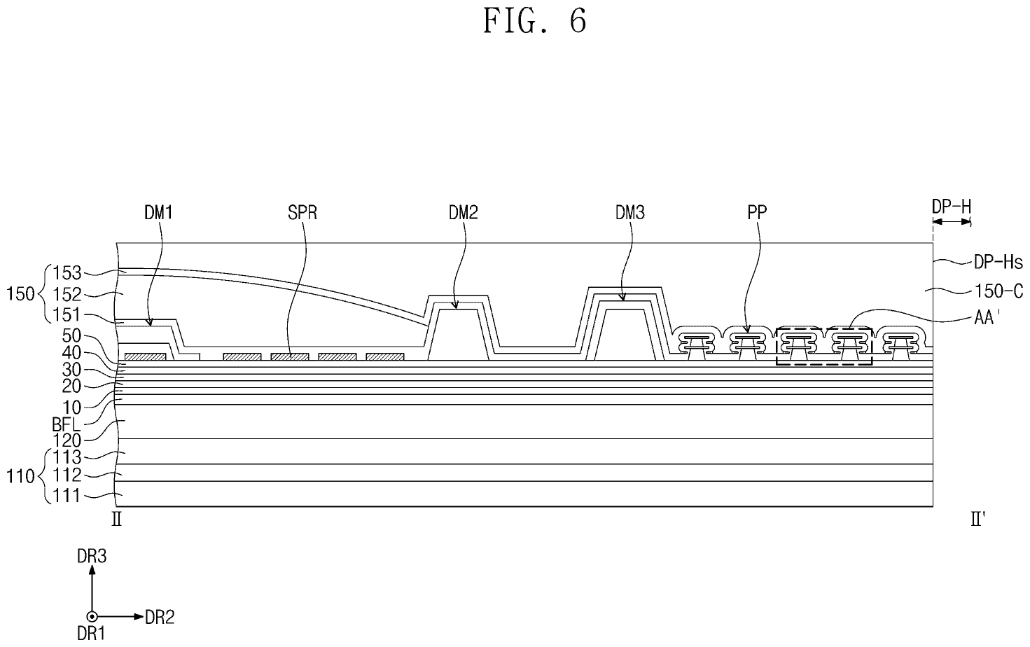

FIG. 6 is a sectional view of the display panel according to an embodiment of the present disclosure. For example, FIG. 6 may be a cross-sectional view taken along the line II-II′ of FIG. 3.

Referring to FIGS. 5 and 6, the display panel DP may include a sidewall DP-Hs that defines the hole DP-H. The display panel DP may further include a plurality of dams DM1, DM2, and DM3 disposed to be adjacent to the hole DP-H, a plurality of separators SPR, and a plurality of protrusions PP.

The plurality of dams DM1, DM2, and DM3 may be provided to control a flow of a monomer during a process of forming the organic encapsulation layer 152. The plurality of dams DM1, DM2, and DM3 may include a first dam DM1, a second dam DM2, and a third dam DM3. Although three dams DM1, DM2, and DM3 are illustrated in the example shown in FIG. 6, the present disclosure is not particularly limited thereto. A part of the three dams DM1, DM2, and DM3 may be omitted, and/or more than the three dams may be disposed.

The first dam DM1 may include a first layer disposed at (e.g., in or on) the same layer as that of the first connecting electrode CNE10, a second layer concurrently (e.g., simultaneously or substantially simultaneously) formed together with the sixth insulating layer 60, and a third layer concurrently (e.g., simultaneously or substantially simultaneously) formed together with the seventh insulating layer 70, but the present disclosure is not particularly limited thereto. The second dam DM2 may be formed of one layer concurrently (e.g., simultaneously or substantially simultaneously) formed together with the seventh insulating layer 70, but the present disclosure is not particularly limited thereto. The third dam DM3 may include a first layer concurrently (e.g., simultaneously or substantially simultaneously) formed together with the seventh insulating layer 70, and a second layer concurrently (e.g., simultaneously or substantially simultaneously) formed together with the eighth insulating layer 80 or with the pixel defining layer PDL, but the present disclosure is not particularly limited thereto.

The plurality of separators SPR may be disposed between the first dam DM1 and the second dam DM2. The plurality of separators SPR may include the same material as that of the first connecting electrode CNE10, and may be disposed at (e.g., in or on) the same layer as that of the first connecting electrode CNE10. Although four separators SPR that are arranged at equal or substantially equal intervals are illustrated as an example in FIG. 6, the present disclosure is not limited thereto. For example, some of the separators SPR may be omitted as needed or desired, all of the separators SPR may be omitted as needed or desired, or more separators SPR may be disposed as needed or desired. Furthermore, the intervals between the separators SPR may differ from one another.

The plurality of separators SPR may be provided to disconnect the intermediate layer CEL, the second electrode CE, and the capping layer CPL. In more detail, the plurality of separators SPR may be provided to disconnect a layer formed as an open mask. The plurality of separators SPR may block a path along which moisture and/or oxygen that may infiltrate through the hole DP-H is introduced into the pixel PX.

The plurality of protrusions PP may be disposed on the base layer 110. The plurality of protrusions PP may be disposed between the pixel PX and the hole DP-H. For example, the plurality of protrusions PP may be disposed between the third dam DM3 and the sidewall DP-Hs. Similar to the plurality of separators SPR, the plurality of protrusions PP may be provided to disconnect the intermediate layer CEL, the second electrode CE, and the capping layer CPL. Furthermore, the plurality of protrusions PP may serve to prevent or substantially prevent the propagation of a crack progressing from the sidewall DP-Hs. Each of the plurality of protrusions PP may have a multi-tip structure, and the plurality of protrusions PP will be described in more detail below.

Although five protrusions PP that are arranged at equal or substantially equal intervals are illustrated as an example in FIG. 6, the present disclosure is not limited thereto. For example, some of the protrusions PP may be omitted as needed or desired, and/or more protrusions PP may be disposed as needed or desired. Furthermore, the intervals between the protrusions PP may differ from one another.

The encapsulation layer 150 may cover the pixel PX, the dams DM1, DM2, and DM3, the separators SPR, and the protrusions PP. A cover layer 150-C for providing a flat or substantially flat upper surface may be additionally disposed on the encapsulation layer 150.

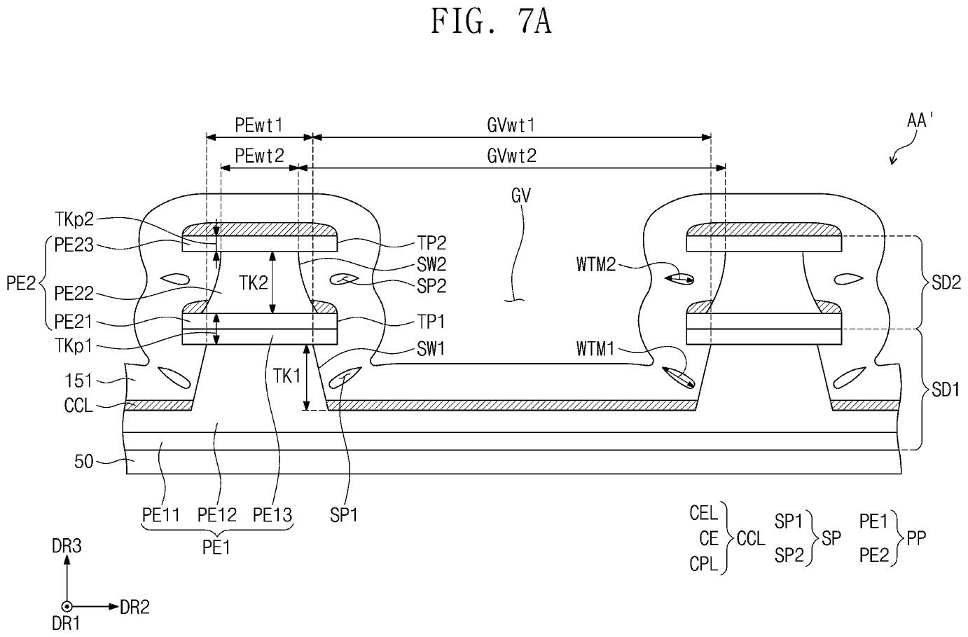

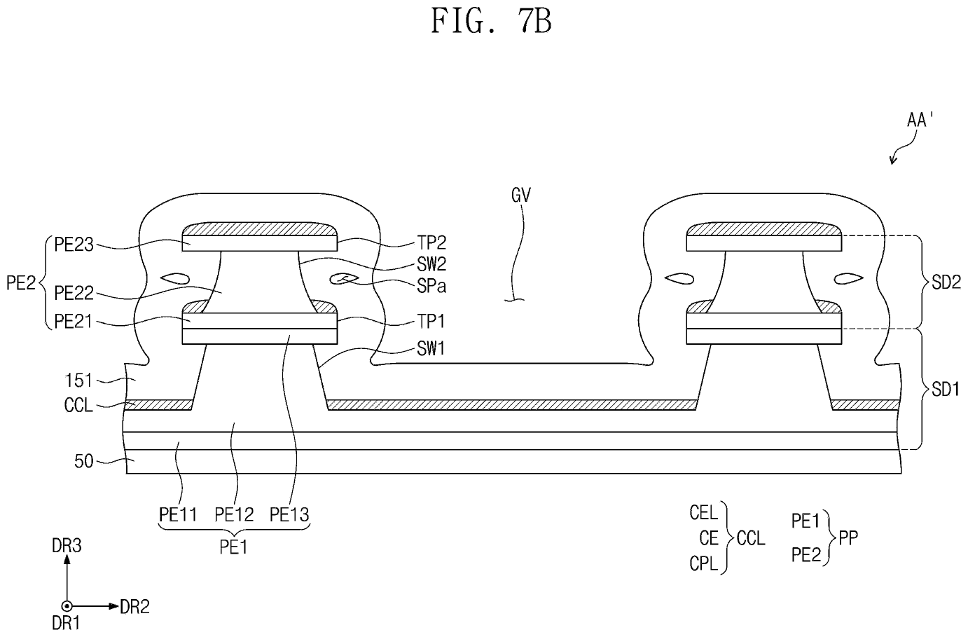

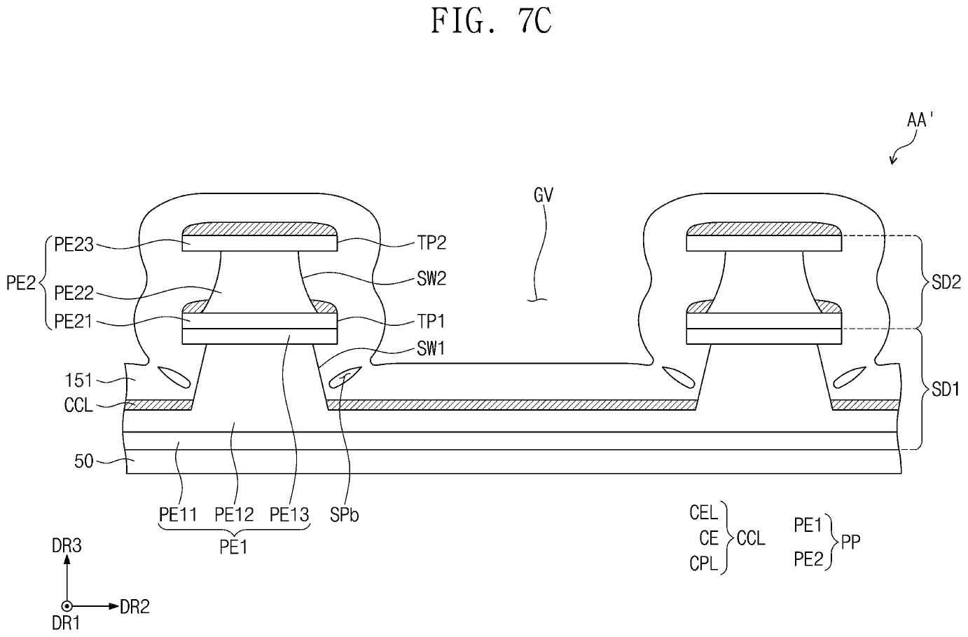

FIG. 7A is an enlarged sectional view of the region AA′ of FIG. 6 according to an embodiment of the present disclosure.

Referring to FIGS. 5, 6, and 7A, one groove GV may be defined between two protrusions PP that are adjacent to each other from among the protrusions PP. A sidewall portion of the groove GV that defines the groove GV may correspond to one or more of the plurality of protrusions PP.

Each of the protrusions PP may include a first sidewall SW1, a first tip TP1 protruding from the first sidewall SW1, a second sidewall SW2 disposed on the first tip TP1, and a second tip TP2 protruding from the second sidewall SW2. In other words, the sidewall portion of the groove GV may include the first sidewall SW1, the first tip TP1 protruding from the first sidewall SW1, the second sidewall SW2 disposed on the first tip TP1, and the second tip TP2 protruding from the second sidewall SW2.

Each of the protrusions PP may include a first conductive portion PE1, and a second conductive portion PE2 directly disposed on the first conductive portion PE1. The first conductive portion PE1 may include a first conductive layer PE11, a second conductive layer PE12, and a third conductive layer PE13, which are sequentially stacked one above another. The second conductive portion PE2 may include a fourth conductive layer PE21, a fifth conductive layer PE22, and a sixth conductive layer PE23, which are sequentially stacked one above another. The first conductive layer PE11, the third conductive layer PE13, the fourth conductive layer PE21, and the sixth conductive layer PE23 may include titanium, and the second conductive layer PE12 and the fifth conductive layer PE22 may include aluminum.

On the section (e.g., in a cross-sectional view), the shape of the first conductive portion PE1 may not be the same as the shape of the second conductive portion PE2. The protrusions PP may be spaced apart from each other in the second direction DR2, and a first width PEwt1 of the first conductive portion PE1 in the second direction DR2 may be greater than a second width PEwt2 of the second conductive portion PE2 in the second direction DR2. The first width PEwt1 may be a minimum width of the first conductive portion PE1 in the second direction DR2, and the second width PEwt2 may be a minimum width of the second conductive portion PE2 in the second direction DR2. The circuit layer 130 may include the plurality of inorganic insulating layers 10, 20, 30, 40, and 50, a first intermediate conductive layer SD1, the sixth insulating layer 60 (e.g., referred to as the first organic layer) that covers the first intermediate conductive layer SD1, and a second intermediate conductive layer SD2 disposed on the first organic layer 60. The first intermediate conductive layer SD1 may be a conductive layer disposed between the fifth insulating layer 50 and the sixth insulating layer 60, and the second intermediate conductive layer SD2 may be a conductive layer disposed between the sixth insulating layer 60 and the seventh insulating layer 70.

The first conductive portion PE1 may be included in the first intermediate conductive layer SD1, and the second conductive portion PE2 may be included in the second intermediate conductive layer SD2. The protrusions PP including the first conductive portion PE1 and the second conductive portion PE2 may be components included in the circuit layer 130. Accordingly, the groove GV defined between the two protrusions PP that are adjacent to each other may be understood as being defined in the circuit layer 130.

An interval between the first conductive portions PE1 of the protrusions PP and an interval between the second conductive portions PE2 of the protrusions PP may correspond to a width of the groove GV in the second direction DR2. For example, a maximum interval between the first conductive portions PE1 of the protrusions PP may correspond to a first width GVwt1 of the groove GV at the first sidewall SW1, and a maximum interval between the second conductive portions PE2 of the protrusions PP may correspond to a second width GVwt2 of the groove GV at the second sidewall SW2. The first width GVwt1 of the groove GV at the first sidewall SW1 may be smaller than the second width GVwt2 of the groove GV at the second sidewall SW2.

The first conductive portion PE1 may be disposed at (e.g., in or on) the same layer as that of the first connecting electrode CNE10, and may include the same material as that of the first connecting electrode CNE10. The second conductive portion PE2 may be disposed at (e.g., in or on) the same layer as that of the second connecting electrode CNE20, and may include the same material as that of the second connecting electrode CNE20.

In an embodiment of the present disclosure, the first conductive layer PE11 and the second conductive layer PE12 of the protrusions PP may be connected with each other, and the third conductive layer PE13, the fourth conductive layer PE21, the fifth conductive layer PE22, and the sixth conductive layer PE23 of the protrusions PP may be separated (e.g., spaced apart) from each other. Accordingly, the protrusions PP may have a mutually electrically connected structure.

The first sidewall SW1 may be defined on at least a portion of the second conductive layer PE12. The first tip TP1 may be defined by the third conductive layer PE13 and the fourth conductive layer PE21. The second sidewall SW2 may be defined in the fifth conductive layer PE22. The second tip TP2 may be defined by the sixth conductive layer PE23. The first tip TP1 includes the third conductive layer PE13 and the fourth conductive layer PE21. Accordingly, a thickness TKp1 of the first tip TP1 may be greater than a thickness TKp2 of the second tip TP2.

The second conductive portion PE2 may be formed by a dry etching process. In this case, the first conductive portion PE1 may also be formed together. For example, when the second conductive portion PE2 is dry etched, about 50% to about 60% of the thickness of the second conductive layer PE12 of the first conductive portion PE1 may be removed together. Accordingly, the first sidewall SW1 may be defined by at least a portion of the second conductive layer PE12.

The plurality of protrusions PP may disconnect a common layer CCL that is formed as an open mask. For example, the common layer CCL may include the intermediate layer CEL, the second electrode CE, and the capping layer CPL. Because the common layer CCL is disconnected by the plurality of protrusions PP, a path along which moisture and/or oxygen that may infiltrate through the hole DP-H is introduced into the pixel PX may be blocked.

According to an embodiment of the present disclosure, the protrusions PP may include a plurality of tips that are stacked in the thickness direction, for example, such as the third direction DR3. Accordingly, the common layer CCL may be more easily disconnected, and thus, a path along which moisture and/or oxygen that may infiltrate through the hole DP-H is introduced into the pixel PX may be more easily blocked

Furthermore, the plurality of separators SPR may have the same or substantially the same structure as that of the first conductive portion PE1. For example, the cross-sectional shape of each of the plurality of separators SPR may be the same or substantially the same as the cross-sectional shape of the first conductive portion PE1 illustrated in FIG. 7A. Accordingly, the common layer CCL may be further disconnected by the plurality of separators SPR.

The first inorganic encapsulation layer 151 may cover the protrusions PP and the groove GV. A plurality of spaces SP completely surrounded (e.g., around peripheries thereof) by the first inorganic encapsulation layer 151 may be defined in the groove GV. The spaces SP may be formed during a process of forming the first inorganic encapsulation layer 151. The spaces SP may be spaces in which the material constituting the first inorganic encapsulation layer 151 is not formed. Accordingly, a gas used during the process of forming the first inorganic encapsulation layer 151 may be accommodated in the spaces SP. The spaces SP may be referred to as cavities, pockets, crack blocking parts, or crack cutting parts.

The spaces SP may include a first space SP1 facing (e.g., adjacent to) the first sidewall SW1, and a second space SP2 facing (e.g., adjacent to) the second sidewall SW2. During the process of forming the first inorganic encapsulation layer 151, the first space SP1 may be formed by the first tip TP1, and the second space SP2 may be formed by the second tip TP2. The first space SP1 and the second space SP2 are spaces in which a liquid or a solid is not disposed. Accordingly, a crack progressing from the sidewall DP-Hs may be blocked by the first space SP1 and the second space SP2. Thus, the product reliability of the display device DD (e.g., refer to FIG. 2A) may be improved.

A first thickness TK1 of the portion defining the first sidewall SW1 of the protrusion PP and a second thickness TK2 of the portion defining the second sidewall SW2 of the protrusion PP may be 1 micrometer or less. For example, the first thickness TK1 and the second thickness TK2 may be 6000 angstroms, but are not particularly limited thereto. In a case in which the first thickness TK1 and the second thickness TK2 exceed 1 micrometer, the spaces SP that are completely surrounded by the first inorganic encapsulation layer 151 may not be formed. According to an embodiment of the present disclosure, the first thickness TK1 and the second thickness TK2 may be various adjusted as needed or desired, such that the spaces SP that are completely surrounded by the first inorganic encapsulation layer 151 are formed.

Referring to FIGS. 6 and 7A, the organic encapsulation layer 152, the second inorganic encapsulation layer 153, and the cover layer 150-C may be sequentially formed after the first inorganic encapsulation layer 151 is formed. For example, in the enlarged region illustrated in FIG. 7A, the second inorganic encapsulation layer 153 may be disposed on the first inorganic encapsulation layer 151. The second inorganic encapsulation layer 153 may have a corrugated shape to correspond to the shape of the first inorganic encapsulation layer 151. The cover layer 150-C is disposed on the second inorganic encapsulation layer 153. Accordingly, at least a portion of the cover layer 150-C may fill the groove GV between the protrusions PP.

On the section (e.g., in a cross-sectional view), a first maximum width WTM1 of the first space SP1 may be greater than a second maximum width WTM2 of the second space SP2. Furthermore, a slope of the direction of the first maximum width WTM1 of the first space SP1 may be greater than a slope of the direction of the second maximum width WTM2 of the second space SP2. For example, the slope may be greater as it is closer to the third direction DR3. For example, when the direction (e.g., the tilt direction) of the first maximum width WTM1 is between the 10 o'clock direction and the 11 o'clock direction or between the 1 o'clock direction and the 2 o'clock direction, the direction of the second maximum width WTM2 may be between the 9 o'clock direction and the 10 o'clock direction or between the 2 o'clock direction and the 3 o'clock direction.

FIG. 7B is an enlarged sectional view of the region AA′ of FIG. 6 according to an embodiment of the present disclosure. In FIG. 7B, the same or substantially the same components as those described above with reference to FIG. 7A are assigned with the same reference numerals, and thus, redundant description thereof may not be repeated.

Referring to FIGS. 5, 6, and 7B, the first inorganic encapsulation layer 151 may cover the protrusions PP and the groove GV. A plurality of spaces SPa that are completely surrounded (e.g., around peripheries thereof) by the first inorganic encapsulation layer 151 may be defined in the groove GV. The spaces SPa may face (e.g., may be adjacent to) the second sidewall SW2. The spaces SPa may serve to block a propagation of a crack progressing from the sidewall DP-Hs.

The spaces SPa may be formed during the process of forming the first inorganic encapsulation layer 151. The spaces SPs may be spaces in which the material constituting the first inorganic encapsulation layer 151 is not formed. Accordingly, a gas used during the process of forming the first inorganic encapsulation layer 151 may be accommodated in the spaces SPa.

FIG. 7C is an enlarged sectional view of the region AA′ of FIG. 6 according to an embodiment of the present disclosure. In FIG. 7C, components that are the same or substantially the same as those described above with reference to FIG. 7A are assigned with the same reference numerals, and thus, redundant description thereof may not be repeated.

Referring to FIGS. 5, 6, and 7C, the first inorganic encapsulation layer 151 may cover the protrusions PP and the groove GV. A plurality of spaces SPb that are completely surrounded (e.g., around peripheries thereof) by the first inorganic encapsulation layer 151 may be defined in the groove GV. The spaces SPb may face (e.g., may be adjacent to) the first sidewall SW1. The spaces SPb may serve to block a propagation of a crack progressing from the sidewall DP-Hs.

The spaces SPb may be formed during the process of forming the first inorganic encapsulation layer 151. The spaces SPb may be spaces in which the material constituting the first inorganic encapsulation layer 151 is not formed. Accordingly, a gas used during the process of forming the first inorganic encapsulation layer 151 may be accommodated in the spaces SPb.

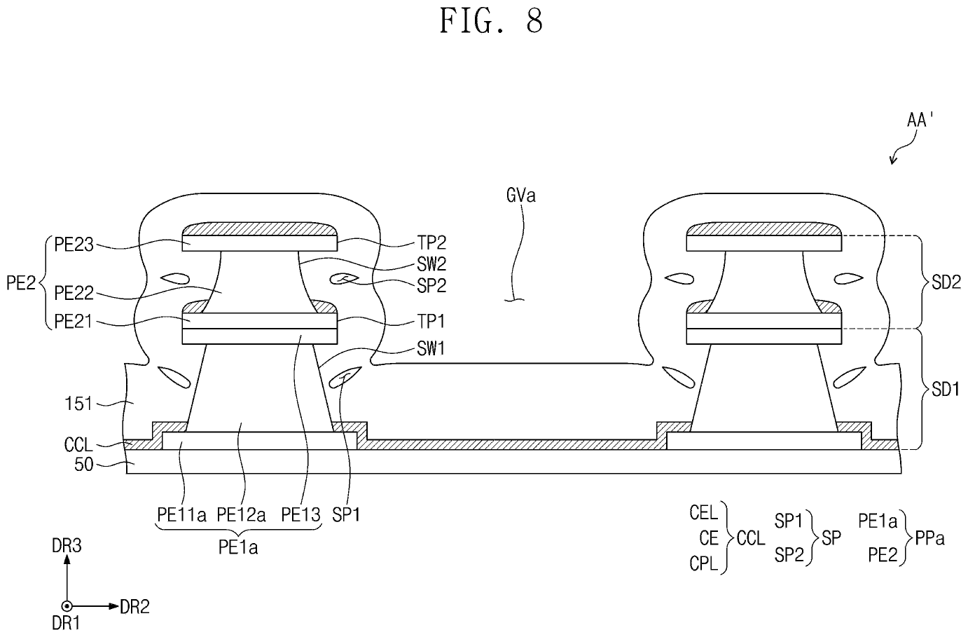

FIG. 8 is an enlarged sectional view of the region AA′ of FIG. 6 according to an embodiment of the present disclosure. In FIG. 8, components that are the same or substantially the same as those described above with reference to FIG. 7A are assigned with the same reference numerals, and thus, redundant description thereof may not be repeated.

Referring to FIG. 8, one groove GVa may be defined between two protrusions PPa that are adjacent to each other from among the protrusions PPa. A sidewall portion of the groove GVa that defines the groove GVa may correspond to one or more of the plurality of protrusions PPa. According to the embodiment illustrated in FIG. 8, the depth of the groove GVa may be greater than the depth of the groove GV illustrated in FIG. 7A. Accordingly, the common layer CCL may be more easily disconnected by the plurality of protrusions PPa.

Each of the protrusions PPa may include a first conductive portion PE1a, and the second conductive portion PE2 directly disposed on the first conductive portion PE1a. The first conductive portion PE1a may include a first conductive layer PE11a, a second conductive layer PE12a, and a third conductive layer PE13, which are sequentially stacked one above another. The second conductive portion PE2 may include the fourth conductive layer PE21, the fifth conductive layer PE22, and the sixth conductive layer PE23, which are sequentially stacked one above another. The first conductive layer PE11a, the third conductive layer PE13, the fourth conductive layer PE21, and the sixth conductive layer PE23 may include titanium, and the second conductive layer PE12a and the fifth conductive layer PE22 may include aluminum.

In an embodiment of the present disclosure, the first conductive layer PE11a, the second conductive layer PE12a, the third conductive layer PE13, the fourth conductive layer PE21, the fifth conductive layer PE22, and the sixth conductive layer PE23 of the protrusions PPa may be separated (e.g., spaced apart) from each other. For example, a first sidewall SW1 may be defined at (e.g., in or on) the second conductive layer PE12a, a first tip TP1 may be defined by the third conductive layer PE13 and the fourth conductive layer PE21, a second sidewall SW2 may be defined at (e.g., in or on) the fifth conductive layer PE22, and a second tip TP2 may be defined by the sixth conductive layer PE23.

In an embodiment of the present disclosure, the first and second conductive portions PE1a and PE2 of the protrusions PPa may be separated (e.g., spaced apart) from each other. For example, when compared to the first conductive layers PE11a and the second conductive layers PE12a illustrated in FIG. 7A, the first conductive layers PE11a of the adjacent protrusions PPa may be electrically isolated from each other, and the second conductive layers PE12a of the adjacent protrusions PPa may be electrically isolated from each other. Accordingly, the protrusions PPa may be completely separated from each other, and may be spaced apart from each other. The protrusions PPa may be electrically insulated from each other.

In an embodiment of the present disclosure, the protrusions PPa may be disposed on the fifth insulating layer 50. The fifth insulating layer 50 may be an inorganic insulating layer including an inorganic material. One groove GVa may be defined between two protrusions PPa, and the protrusions PPa may be completely separated from each other and may be spaced apart from each other. Accordingly, the sidewall portion of the groove GVa that defines the groove GVa may correspond to one or more of the plurality of protrusions PPa, and a bottom portion of the groove GVa may be a portion of the fifth insulating layer 50 that is exposed between the protrusions PPa. Accordingly, in the groove GVa, the common layer CCL may make direct contact with the fifth insulating layer 50.

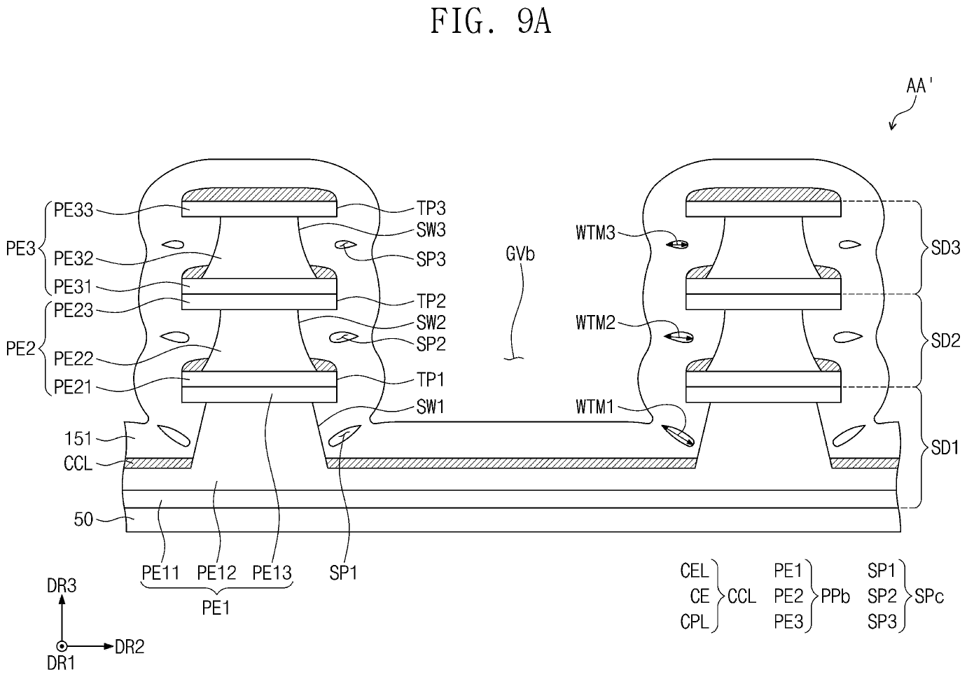

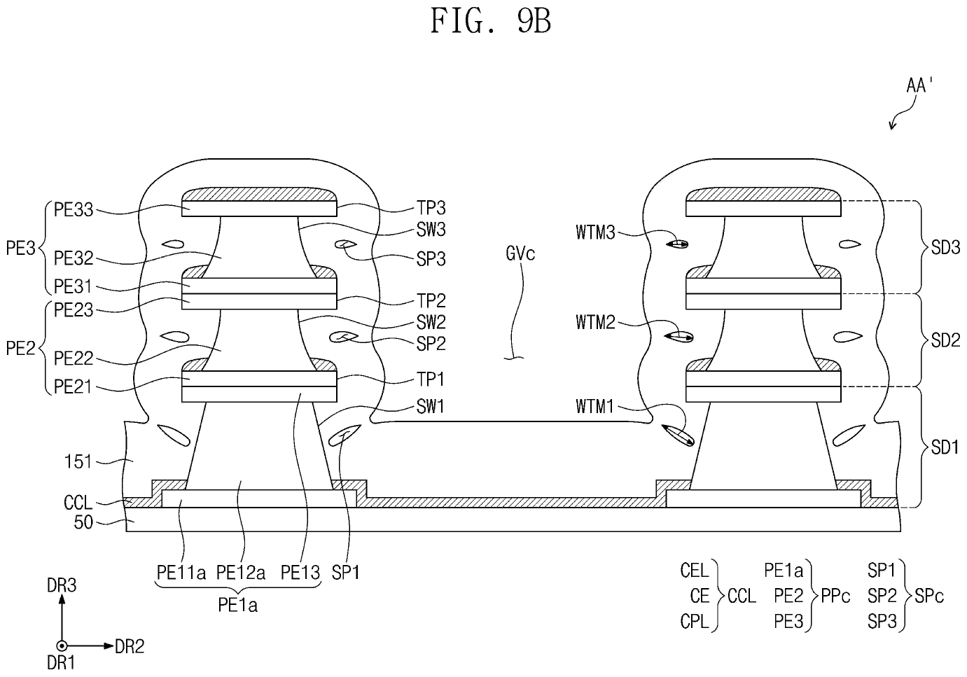

FIG. 9A is an enlarged sectional view of the region AA′ of FIG. 6 according to an embodiment of the present disclosure. In FIG. 9A, components that are the same or substantially the same as those described above with reference to FIG. 7A are assigned with the same reference numerals, and thus, redundant description thereof may not be repeated.

Referring to FIGS. 5 and 9A, one groove GVb may be defined between two protrusions PPb that are adjacent to each other from among the protrusions PPb. A sidewall portion of the groove GVb that defines the groove GVb may correspond to one or more of the plurality of protrusions PPb.

Each of the protrusions PPb may include a first sidewall SW1, a first tip TP1 protruding from the first sidewall SW1, a second sidewall SW2 disposed on the first tip TP1, a second tip TP2 protruding from the second sidewall SW2, a third sidewall SW3 disposed on the second tip TP2, and a third tip TP3 protruding from the third sidewall SW3.

Each of the protrusions PPb may include a first conductive portion PE1, a second conductive portion PE2 directly disposed on the first conductive portion PE1, and a third conductive portion PE3 directly disposed on the second conductive portion PE2. The third conductive portion PE3 may include a seventh conductive layer PE31, an eighth conductive layer PE32, and a ninth conductive layer PE3, which are sequentially stacked one above another. A first conductive layer PE11, a third conductive layer PE13, a fourth conductive layer PE21, a sixth conductive layer PE23, the seventh conductive layer PE31, and the ninth conductive layer PE33 may include titanium, and a second conductive layer PE12, a fifth conductive layer PE22, and the eighth conductive layer PE32 may include aluminum.

The circuit layer 130 may include the plurality of inorganic insulating layers 10, 20, 30, 40, and 50, a first intermediate conductive layer SD1, the sixth insulating layer 60 (e.g., referred to as the first organic layer) that covers the first intermediate conductive layer SD1, a second intermediate conductive layer SD2 disposed on the first organic layer 60, the seventh insulating layer 70 (e.g., referred to as the second organic layer) that covers the second intermediate conductive layer SD2, and a third intermediate conductive layer SD3 disposed on the second organic layer 70.

The third intermediate conductive layer SD3 may be a conductive layer disposed between the seventh insulating layer 70 and the eighth insulating layer 80, and the third conductive portion PE3 may be included in the third intermediate conductive layer SD3. Accordingly, the third conductive portion PE3 may be disposed at (e.g., in or on) the same layer as that of the third connecting electrode CNE30, and may include the same material as that of the third connecting electrode CNE30.

The plurality of protrusions PPb may disconnect the common layer CCL formed as an open mask. For example, the common layer CCL may include the intermediate layer CEL, the second electrode CE, and the capping layer CPL. Because the common layer CCL is disconnected by the plurality of protrusions PPb, a path along which moisture and/or oxygen that may infiltrate through the hole DP-H is introduced into the pixel PX may be blocked.

The first inorganic encapsulation layer 151 may cover the protrusions PPb and the groove GVb. A plurality of spaces SPc that are completely surrounded (e.g., around peripheries thereof) by the first inorganic encapsulation layer 151 may be defined in the groove GVb. The spaces SPc may be formed during the process of forming the first inorganic encapsulation layer 151. The spaces SPc may be spaces in which the material constituting the first inorganic encapsulation layer 151 is not formed. Accordingly, a gas used during the process of forming the first inorganic encapsulation layer 151 may be accommodated in the spaces SPc.

The spaces SPc may include a first space SP1 facing (e.g., adjacent to) the first sidewall SW1, a second space SP2 facing (e.g., adjacent to) the second sidewall SW2, and a third space SP3 facing (e.g., adjacent to) the third sidewall SW3. During the process of forming the first inorganic encapsulation layer 151, the first space SP1 may be formed by the first tip TP1, the second space SP2 may be formed by the second tip TP2, and the third space SP3 may be formed by the third tip TP3. The first space SP1, the second space SP2, and the third space SP3 may serve to block a propagation of a crack progressing from the sidewall DP-Hs. In an embodiment of the present disclosure, at least one of the first to third spaces SP1, SP2, and SP3 may be omitted.

On the section (e.g., in a cross-sectional view), a first maximum width WTM1 of the first space SP1 may be greater than a second maximum width WTM2 of the second space SP2, and the second maximum width WTM2 of the second space SP2 may be greater than a third maximum width WTM3 of the third space SP3. Furthermore, the direction of the first maximum width WTM1, the direction of the second maximum width WTM2, and the direction of the third maximum width WTM3 may differ from one another. For example, the slope of the direction of the first maximum width WTM1 may be greater than the slope of the direction of the second maximum width WTM2, and the slope of the direction of the second maximum width WTM2 may be greater than the slope of the direction of the third maximum width WTM3. Here, the slope may be greater as it is closer to the third direction DR3.

FIG. 9B is an enlarged sectional view of the region AA′ of FIG. 6 according to an embodiment of the present disclosure. In FIG. 9B, components that are the same or substantially the same as those described above with reference to FIGS. 7A and 9A are assigned with the same reference numerals, and thus, redundant description thereof may not be repeated.

Referring to FIG. 9B, one groove GVc may be defined between two protrusions PPc that are adjacent to each other from among the protrusions PPc. A sidewall portion of the groove GVc that defines the groove GVc may correspond to one or more of the plurality of protrusions PPc.

Each of the protrusions PPc may include a first conductive portion PE1a, a second conductive portion PE2 directly disposed on the first conductive portion PE1a, and a third conductive portion PE3 directly disposed on the second conductive portion PE2.

In an embodiment of the present disclosure, the first to third conductive portions PE1a, PE2, and PE3 of the protrusions PPc may be separated from each other. For example, when compared to the first conductive portions illustrated in FIG. 9A, the first conductive portions PE1a of the adjacent protrusions PPc may be electrically isolated from each other. Accordingly, the protrusions PPc may be completely separated from each other, and may be spaced apart from each other. The protrusions PPc may be electrically insulated from each other.

In an embodiment of the present disclosure, the protrusions PPc may be disposed on the fifth insulating layer 50. The fifth insulating layer 50 may be an inorganic insulating layer including an inorganic material. One groove GVc may be defined between two protrusions PPc, and the protrusions PPc may be completely separated from each other and may be spaced apart from each other. Accordingly, the sidewall portion of the groove GVc that defines the groove GVc may correspond to the plurality of protrusions PPc, and a bottom portion of the groove GVc may be a portion of the fifth insulating layer 50 that is exposed between the protrusions PPc. Accordingly, in the groove GVc, the common layer CCL may make direct contact with the fifth insulating layer 50.

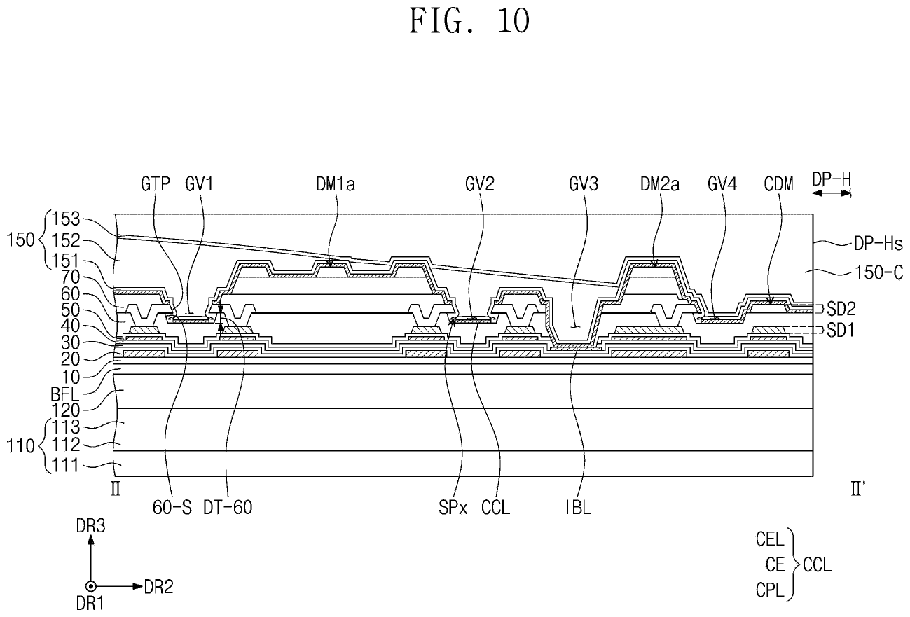

FIG. 10 is a sectional view of the display panel according to an embodiment of the present disclosure. For example, FIG. 10 may be a cross-sectional view taken along the line II-II′ of FIG. 3.

Referring to FIGS. 3, 5, and 10, the display panel DP may include the sidewall DP-Hs that defines the hole DP-H. The display panel DP may include a plurality of dams DM1a and DM2a that are disposed adjacent to the hole DP-H, a crack dam CDM, and a plurality of grooves GV1, GV2, GV3, and GV4.

The plurality of dams DM1a and DM2a may be provided to control a flow of a monomer during the process of forming the organic encapsulation layer 152. The plurality of dams DM1a and DM2a may include a first dam DM1a and a second dam DM2a. The crack dam CDM may serve to prevent or substantially prevent a propagation of a crack progressing from the sidewall DP-Hs.

The circuit layer 130 may include the plurality of inorganic insulating layers 10, 20, 30, 40, and 50, a first intermediate conductive layer SD1, the sixth insulating layer 60 (e.g., referred to as the first organic layer) that covers the first intermediate conductive layer SD1, and a second intermediate conductive layer SD2 disposed on the first organic layer 60. The first intermediate conductive layer SD1 may be a conductive layer disposed between the fifth insulating layer 50 and the sixth insulating layer 60, and the second intermediate conductive layer SD2 may be a conductive layer disposed between the sixth insulating layer 60 and the seventh insulating layer 70.

The plurality of grooves GV1, GV2, GV3, and GV4 may include the first groove GV1, the second groove GV2, the third groove GV3, and the fourth groove GV4.

The first groove GV1, the second groove GV2, and the fourth groove GV4 may be defined in the sixth insulating layer 60. The first groove GV1, the second groove GV2, and the fourth groove GV4 may be provided to disconnect the common layer CCL formed as an open mask. Accordingly, a tip GTP further protruding beyond a sidewall 60-S of the sixth insulating layer 60 that defines the first groove GV1, the second groove GV2, and the fourth groove GV4 may overlap with the first groove GV1, the second groove GV2, and the fourth groove GV4. Referring to FIG. 10, the first groove GV1 and the second groove GV2 may overlap with two tips GTP, and the fourth groove GV4 may overlap with one tip GTP.

The third groove GV3 may be provided by removing portions of the fourth, fifth, sixth, and seventh insulating layers 40, 50, 60, and 70. The third groove GV3 may be provided to control a flow of a monomer. A shielding layer IBL may be disposed on a bottom surface of the third groove GV3. The shielding layer IBL may be formed from the second semiconductor pattern. Accordingly, the shielding layer IBL may be disposed between the third insulating layer 30 and the fourth insulating layer 40, and may include indium zinc oxide (IZO). In an embodiment of the present disclosure, the shielding layer IBL may be omitted.

The display panel DP may further include the crack dam CDM disposed between the hole DP-H and the light emitting element ED. The crack dam CDM may be closer to the hole DP-H than the plurality of dams DM1a and DM2a and the plurality of grooves GV1, GV2, GV3, and GV4. The crack dam CDM may serve to block a propagation of a crack progressing from the sidewall DP-Hs.

The encapsulation layer 150 may cover the circuit layer 130 and the element layer 140. Accordingly, the encapsulation layer 150 may cover all of the plurality of dams DM1a and DM2a, the crack dam CDM, and the plurality of grooves GV1, GV2, GV3, and GV4. A plurality of spaces SPx completely surrounded (e.g., around peripheries thereof) by the first inorganic encapsulation layer 151 may be defined in the first groove GV1, the second groove GV2, and the fourth groove GV4. The spaces SPx may be formed during the process of forming the first inorganic encapsulation layer 151. The spaces SPx may be spaces in which the material constituting the first inorganic encapsulation layer 151 is not formed. Accordingly, a gas used during the process of forming the first inorganic encapsulation layer 151 may be accommodated in the spaces SPx. A crack progressing from the sidewall DP-Hs may be blocked by the spaces SPx.

In an embodiment of the present disclosure, the depth DT-60 of each of the first groove GV1, the second groove GV2, and the fourth groove GV4 may be 1 micrometer or less. For example, the depth DT-60 may be 6000 angstroms, but is not particularly limited thereto. In a case in which the depth DT-60 exceeds 1 micrometer, the spaces SPx that are completely surrounded by the first inorganic encapsulation layer 151 may not be formed. According to an embodiment of the present disclosure, the depth DT-60 may be adjusted, such that the spaces SPx that are completely surrounded by the first inorganic encapsulation layer 151 are formed.

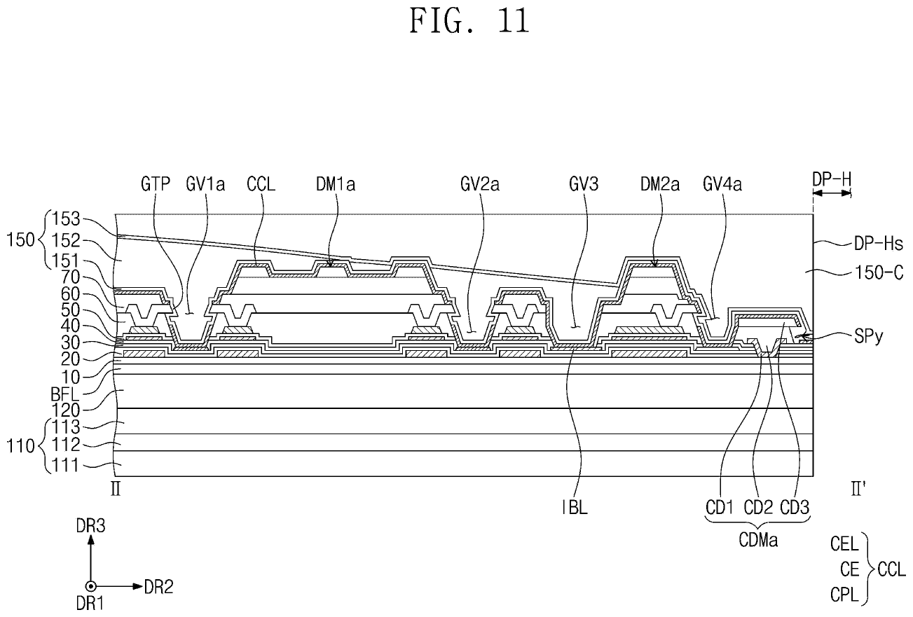

FIG. 11 is a sectional view of the display panel according to an embodiment of the present disclosure. For example, FIG. 11 may be a cross-sectional view taken along the line II-II′ of FIG. 3. In FIG. 11, components that are the same or substantially the same as those illustrated in FIG. 10 are assigned with the same reference numerals, and thus, redundant description thereof may not be repeated.

Referring to FIGS. 3, 5, and 11, the display panel DP may include the sidewall DP-Hs that defines the hole DP-H. The display panel DP may include a plurality of dams DM1a and DM2a that are disposed adjacent to the hole DP-H, a crack dam CDMa, and a plurality of grooves GV1a, GV2a, GV3, and GV4a.

The plurality of grooves GV1a, GV2a, GV3, and GV4a may be provided to control a flow of a monomer. The plurality of grooves GV1a, GV2a, GV3, and GV4a may be provided by removing portions of the fourth, fifth, sixth, and seventh insulating layers 40, 50, 60, and 70. A shielding layer IBL may be disposed on a bottom surface of each of the plurality of grooves GV1a, GV2a, GV3, and GV4a. In an embodiment of the present disclosure, the shielding layer IBL may be omitted.

At least some of the plurality of grooves GV1a, GV2a, GV3, and GV4a may be provided to disconnect the common layer CCL formed as an open mask. Accordingly, a tip GTP further protruding beyond a sidewall 60-S of the sixth insulating layer 60 that defines the first groove GV1a, the second groove GV2a, and the fourth groove GV4a may overlap with the first groove GV1a, the second groove GV2a, and the fourth groove GV4a.

The display panel DP may further include the crack dam CDMa disposed between the hole DP-H and the light emitting element ED. The crack dam CDMa may be closer to the hole DP-H than the plurality of dams DM1a and DM2a and the plurality of grooves GV1a, GV2a, GV3, and GV4a. The crack dam CDMa may serve to block a propagation of a crack progressing from the sidewall DP-Hs.

The crack dam CDMa may include a first layer CD1, a second layer CD2, and a third layer CD3. The first layer CD1 may include the same material as that of the first connecting electrode CNE10, and may be disposed at (e.g., in or on) the same layer as that of the first connecting electrode CNE10. The second layer CD2 may include the same material as that of the sixth insulating layer 60. The third layer CD3 may be included in the second intermediate conductive layer SD2 (e.g., refer to FIG. 10). The third layer CD3 may include the same material as that of the second connecting electrode CNE20.

The third layer CD3 may further protrude toward the sidewall DP-Hs beyond the second layer CD2. Accordingly, the third layer CD3 may serve as a tip in the crack dam CDMa. The second layer CD2 may have a thickness of 1 micrometer or less. For example, the second layer CD2 may have a thickness of 6000 angstroms, but is not particularly limited thereto.

The encapsulation layer 150 may cover all of the plurality of dams DM1a and DM2a, the crack dam CDMa, and the plurality of grooves GV1a, GV2a, GV3, and GV4a. A space SPy that is completely surrounded (e.g., around a periphery thereof) by the encapsulation layer 150 may be defined in a portion that faces (e.g., that is adjacent to) the second layer CD2. The space SPy may be formed by the third layer CD3 during the process of forming the first inorganic encapsulation layer 151. Thus, according to an embodiment of the present disclosure, crack propagation may be more easily blocked as the space SPy is defined between the crack dam CDMa and the sidewall DP-Hs.

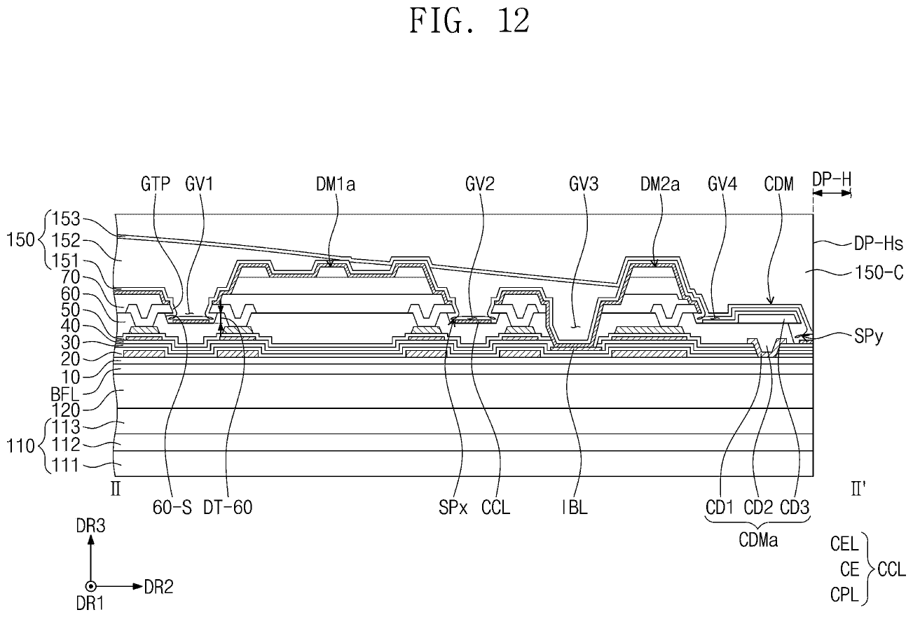

FIG. 12 is a sectional view of the display panel according to an embodiment of the present disclosure. For example, FIG. 12 may be a cross-sectional view taken along the line II-II′ of FIG. 3. The structure illustrated in FIG. 12 may be a structure in which the structure described above with reference to FIG. 10 is merged with the structure described above with reference to FIG. 11.

Referring to FIGS. 3, 5, and 12, the display panel DP may include the sidewall DP-Hs that defines the hole DP-H. The display panel DP may include a plurality of dams DM1a and DM2a that are disposed adjacent to the hole DP-H, a crack dam CDM, and a plurality of grooves GV1, GV2, GV3, and GV4.

The encapsulation layer 150 may cover all of the plurality of dams DM1a and DM2a, the crack dam CDMa, and the plurality of grooves GV1, GV2, GV3, and GV4. A plurality of spaces SPx that are completely surrounded (e.g., around peripheries thereof) by the first inorganic encapsulation layer 151 may be defined in the first groove GV1, the second groove GV2, and the fourth groove GV4. A space SPy that is completely surrounded (e.g., around a periphery thereof) by the first inorganic encapsulation layer 151 may be defined in a portion that faces (e.g., that is adjacent to) the second layer CD2.

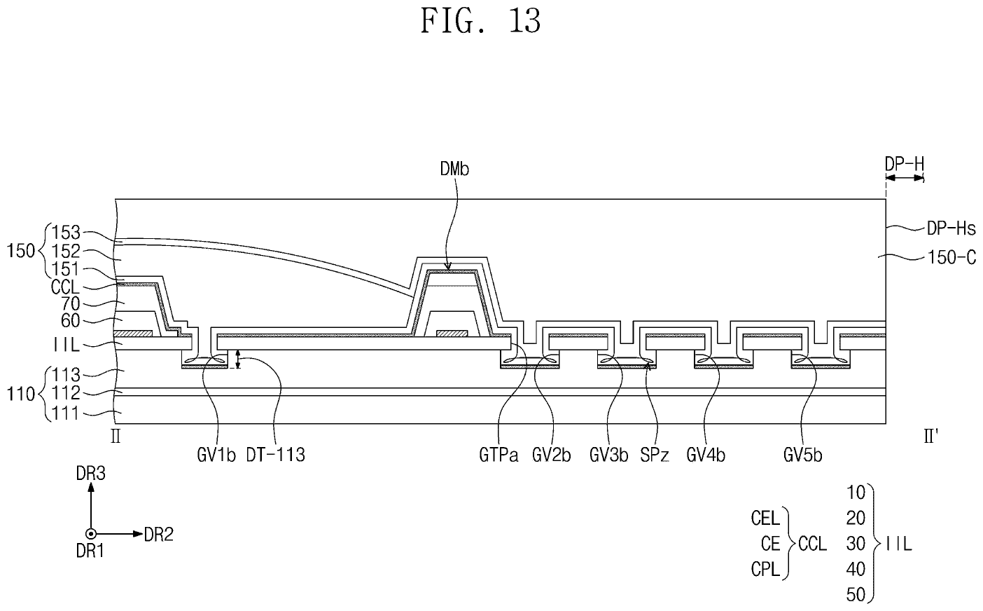

FIG. 13 is a sectional view of the display panel according to an embodiment of the present disclosure. For example, FIG. 13 may be a cross-sectional view taken along the line II-II′ of FIG. 3.

Referring to FIGS. 3, 5, and 13, the display panel DP may include the sidewall DP-Hs that defines the hole DP-H. The display panel DP may include a dam DMb disposed to be adjacent to the hole DP-H, and a plurality of grooves GV1b, GV2b, GV3b, GV4b, and GV5b.

The plurality of grooves GV1b, GV2b, GV3b, GV4b, and GV5b may be defined in the base layer 110. For example, the plurality of grooves GV1b, GV2b, GV3b, GV4b, and GV5b may be defined in the third sub-base layer 113. Although five grooves GV1b, GV2b, GV3b, GV4b, and GV5b are illustrated as an example in FIG. 13, the number of grooves GV1b, GV2b, GV3b, GV4b, and GV5b is not limited thereto.

The plurality of grooves GV1b, GV2b, GV3b, GV4b, and GV5b may be provided to disconnect the common layer CCL formed as an open mask. Accordingly, a tip GTPa further protruding beyond the sidewall defining each of the plurality of grooves GV1b, GV2b, GV3b, GV4b, and GV5b may overlap with the plurality of grooves GV1b, GV2b, GV3b, GV4b, and GV5b. The tip GTPa may be defined by a plurality of inorganic insulating layers IIL. The inorganic insulating layers IIL may include the first to fifth insulating layers 10, 20, 30, 40, and 50.

The encapsulation layer 150 may cover the dam DMb and the plurality of grooves GV1b, GV2b, GV3b, GV4b, and GV5b. A plurality of spaces SPz that are completely surrounded (e.g., around peripheries thereof) by the first inorganic encapsulation layer 151 may be defined in the grooves GV1b, GV2b, GV3b, GV4b, and GV5b. A crack progressing from the sidewall DP-Hs may be blocked by the spaces SPz.

In an embodiment of the present disclosure, the depth DT-113 of each of the grooves GV1b, GV2b, GV3b, GV4b, and GV5b may be 1 micrometer or less. For example, the depth DT-113 may be 6000 angstroms, but is not particularly limited thereto.

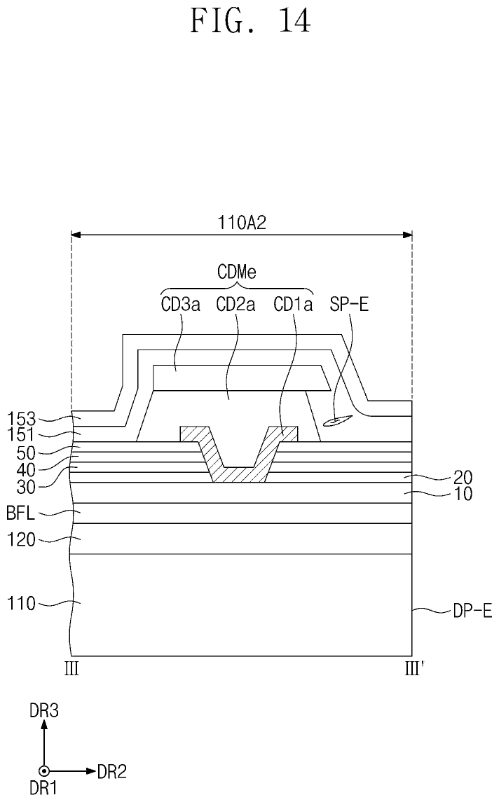

FIG. 14 is a sectional view of the display panel according to an embodiment of the present disclosure. For example, FIG. 14 is a cross-sectional view taken along the line III-III′ of FIG. 3.

Referring to FIGS. 3 and 14, a crack dam CDMe may be disposed in a region adjacent to an edge DP-E of the display panel DP. The light emitting element ED may be disposed to overlap with the first region 110A1 of the base layer 110 (e.g., see FIG. 3), and the crack dam CDMe may be disposed to overlap with the second region 110A2 of the base layer 110.

On the plane (e.g., in a plan view), the crack dam CDMe may have a shape surrounding (e.g., around a periphery of) at least a portion of the display region DP-DA of the display panel DP. The crack dam CDMe may serve to block a crack progressing from the edge DP-E of the display panel DP from propagating into the display region DP-DA.

In an embodiment of the present disclosure, the crack dam CDMe may include a first layer CD1a, a second layer CD2a, and a third layer CD3a. The first layer CD1a may include the same material as that of the first connecting electrode CNE10, and may be disposed at (e.g., in or on) the same layer as that of the first connecting electrode CNE10. The second layer CD2a may include the same material as that of the sixth insulating layer 60. The third layer CD3a may include the same material as that of the second connecting electrode CNE20.

The third layer CD3a may further protrude toward the edge DP-E of the display panel DP beyond the second layer CD2a. Accordingly, the third layer CD3a may serve as a tip in the crack dam CDMe. The second layer CD2a may have a thickness of 1 micrometer or less. For example, the second layer CD2a may have a thickness of 6000 angstroms, but is not particularly limited thereto.

A space SP-E that is completely surrounded (e.g., around a periphery thereof) by the first inorganic encapsulation layer 151 may be defined in a portion that faces (e.g., that is adjacent to) the second layer CD2a. The space SP-E may be formed by the third layer CD3a during the process of forming the first inorganic encapsulation layer 151. Thus, according to an embodiment of the present disclosure, a crack propagation may be more easily blocked as the space SP-E is defined between the crack dam CDMe and the edge DP-E of the display panel DP.

As described above, the first inorganic encapsulation layer may cover the protrusions and the groove. The plurality of spaces that are completely surrounded (e.g., around peripheries thereof) by the first inorganic encapsulation layer may be defined in the groove. The spaces may be spaces in which the material constituting the first inorganic encapsulation layer is not formed. The plurality of spaces may block a propagation of a crack progressing from the sidewall of the display panel. Accordingly, the product reliability of the display device may be improved.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a base layer;
a circuit layer on the base layer, and comprising a pixel circuit;
an element layer on the circuit layer, and comprising a light emitting element electrically connected with the pixel circuit; and
an encapsulation layer covering the element layer,
wherein at least one of the base layer or the circuit layer has a groove defined therein,
wherein the encapsulation layer covers the groove, and
wherein a plurality of spaces are defined in the groove, each of the plurality of spaces being completely surrounded by the encapsulation layer.

2. The display device of claim 1, wherein the groove comprises a sidewall portion comprising:
a first sidewall;
a first tip protruding from the first sidewall;
a second sidewall on the first tip; and
a second tip protruding from the second sidewall.

3. The display device of claim 2, wherein a first width of the groove at the first sidewall is smaller than a second width of the groove at the second sidewall.

4. The display device of claim 2, wherein the circuit layer further comprises:
a plurality of inorganic insulating layers;
a first intermediate conductive layer;
a first organic layer on the plurality of inorganic insulating layers, and covering the first intermediate conductive layer; and
a second intermediate conductive layer on the first organic layer,
wherein the first intermediate conductive layer comprises a first conductive layer, a second conductive layer, and a third conductive layer sequentially stacked one above another,
wherein the second intermediate conductive layer comprises a fourth conductive layer, a fifth conductive layer, and a sixth conductive layer sequentially stacked one above another, and
wherein:
the first sidewall is defined in at least a portion of the second conductive layer;
the first tip is defined by the third conductive layer and the fourth conductive layer;
the second sidewall is defined in the fifth conductive layer; and
the second tip is defined by the sixth conductive layer.

5. The display device of claim 4, wherein the first conductive layer, the third conductive layer, the fourth conductive layer, and the sixth conductive layer comprise titanium, and
wherein the second conductive layer and the fifth conductive layer comprise aluminum.

6. The display device of claim 2, wherein the plurality of spaces comprises:
a first space facing the first sidewall; and
a second space facing the second sidewall.

7. The display device of claim 6, wherein, in a cross-sectional view, a maximum width of the first space is greater than a maximum width of the second space.

8. The display device of claim 7, wherein a slope of a direction of the maximum width of the first space is greater than a slope of a direction of the maximum width of the second space.

9. The display device of claim 2, wherein the groove further comprises a third sidewall on the second tip, and a third tip protruding from the third sidewall.

10. The display device of claim 9, wherein the plurality of spaces comprises:
a first space facing the first sidewall;
a second space facing the second sidewall; and
a third space facing the third sidewall, and
wherein, in a cross-sectional view, a first maximum width of the first space is greater than a second maximum width of the second space, and the second maximum width of the second space is greater than a third maximum width of the third space.

11. The display device of claim 10, wherein a direction of the first maximum width of the first space, a direction of the second maximum width of the second space, and a direction of the third maximum width of the third space are different from one another.

12. The display device of claim 2, wherein a thickness of the first tip is greater than a thickness of the second tip.

13. The display device of claim 2, wherein each of a portion defining the first sidewall and a portion defining the second sidewall has a thickness of 1 micrometer or less.

14. The display device of claim 1, wherein the groove is defined in the base layer, and has a depth of 1 micrometer or less.

15. The display device of claim 14, wherein the circuit layer further comprises:
a plurality of inorganic insulating layers;
a first intermediate conductive layer;
a first organic layer on the plurality of inorganic insulating layers, and covering the first intermediate conductive layer; and
a second intermediate conductive layer on the first organic layer, and
wherein the plurality of inorganic insulating layers have a tip portion protruding more than a sidewall of the base layer defining the groove.

16. The display device of claim 1, wherein the circuit layer further comprises:
a plurality of inorganic insulating layers;
a first intermediate conductive layer;
a first organic layer on the plurality of inorganic insulating layers, and covering the first intermediate conductive layer; and
a second intermediate conductive layer on the first organic layer, and
wherein the groove is defined in the first organic layer, and the second intermediate conductive layer defines a tip portion protruding more than a sidewall of the first organic layer defining the groove.

17. The display device of claim 16, further comprising a crack dam spaced from the light emitting element, and comprising:
a first layer comprising the same material as that of the first organic layer; and
a second layer comprising the same material as that of the second intermediate conductive layer,
wherein the second layer protrudes more than the first layer,
wherein the encapsulation layer covers the crack dam, and
wherein a space completely surrounded by the encapsulation layer is further defined in a portion facing the first layer.

18. The display device of claim 17, wherein the base layer has a hole, and
wherein the crack dam is located between the hole and the light emitting element.

19. The display device of claim 17, wherein the base layer comprises:
a first region, the light emitting element being located in the first region; and
a second region surrounding the first region, the crack dam being located in the second region.

20. The display device of claim 1, wherein the encapsulation layer comprises:
a first inorganic encapsulation layer on the element layer;
an organic encapsulation layer on the first inorganic encapsulation layer; and
a second inorganic encapsulation layer on the organic encapsulation layer, and
wherein each of the plurality of spaces is surrounded by the first inorganic encapsulation layer.

21. A display device comprising:
a base layer having a hole defined therein;
a pixel on the base layer, and comprising a first electrode, an intermediate layer, and a second electrode;
a protrusion on the base layer between the pixel and the hole, and comprising:
a first sidewall;
a first tip protruding from the first sidewall;
a second sidewall on the first tip; and
a second tip protruding from the second sidewall;
an encapsulation layer covering the pixel and the protrusion; and
a space completely surrounded by the encapsulation layer,
wherein the space faces at least one of the first sidewall or the second sidewall of the protrusion.

22. The display device of claim 21, wherein the space comprises:
a first space facing the first sidewall; and
a second space facing the second sidewall.

23. The display device of claim 22, wherein, in a cross-sectional view, a maximum width of the first space is greater than a maximum width of the second space.

24. The display device of claim 23, wherein a slope of a direction of the maximum width of the first space is greater than a slope of a direction of the maximum width of the second space.

25. The display device of claim 21, wherein the protrusion comprises:
a first conductive portion comprising a first conductive layer, a second conductive layer, and a third conductive layer sequentially stacked one above another; and
a second conductive portion comprising a fourth conductive layer, a fifth conductive layer, and a sixth conductive layer sequentially stacked one above another, and
wherein:
the first sidewall is defined in at least a portion of the second conductive layer;
the first tip is defined by the third conductive layer and the fourth conductive layer;
the second sidewall is defined in the fifth conductive layer; and
the second tip is defined by the sixth conductive layer.

26. The display device of claim 25, wherein the protrusion comprises a plurality of protrusions,
wherein the first conductive layer and the second conductive layer of the plurality of protrusions are connected with each other, and
wherein the third conductive layer, the fourth conductive layer, the fifth conductive layer, and the sixth conductive layer of the plurality of protrusions are spaced from each other.

27. The display device of claim 25, wherein the first conductive layer, the third conductive layer, the fourth conductive layer, and the sixth conductive layer comprise titanium, and
wherein the second conductive layer and the fifth conductive layer comprise aluminum.

28. The display device of claim 25, wherein a minimum width of the first conductive portion is greater than a minimum width of the second conductive portion.

29. The display device of claim 25, wherein the protrusion comprises a plurality of protrusions, and
wherein a maximum interval between the first conductive portions of the plurality of protrusions is smaller than a maximum interval between the second conductive portions of the plurality of protrusions.

30. The display device of claim 21, wherein a thickness of the first tip is greater than a thickness of the second tip.

31. The display device of claim 21, wherein the protrusion further comprises a third sidewall on the second tip, and a third tip protruding from the third sidewall.

32. The display device of claim 31, wherein the space comprises:
a first space facing the first sidewall;
a second space facing the second sidewall; and
a third space facing the third sidewall, and
wherein, in a cross-sectional view, a first maximum width of the first space is greater than a second maximum width of the second space, and the second maximum width of the second space is greater than a third maximum width of the third space.

33. The display device of claim 32, wherein a direction of the first maximum width of the first space, a direction of the second maximum width of the second space, and a direction of the third maximum width of the third space are different from one another.

34. The display device of claim 21, wherein each of a portion defining the first sidewall of the protrusion and a portion defining the second sidewall of the protrusion has a thickness of 1 micrometer or less.
